(19) United States
(12) Patent Application Publication
(10) Pub. No.: US 2024/0324392 A1
(43) Pub. Date: Sep. 26, 2024

(54) Display Device And Method For Manufacturing Display Device

(71) Applicant: Semiconductor Energy Laboratory Co., Ltd., Kanagawa-ken (JP)

(72) Inventors: Shunpei YAMAZAKI, Setagaya, Tokyo (JP); Satoshi SEO, Sagamihara, Kanagawa (JP); Kenichi OKAZAKI, Atsugi, Kanagawa (JP)

(73) Assignee: Semiconductor Energy Laboratory Co., Ltd., Kanagawa-ken (JP)

(21) Appl. No.: 18/273,860

(22) PCT Filed: Jan. 18, 2022
(86) PCT No.: PCT/IB2022/050366

§ 371 Date: Jul. 24, 2023

(30) Foreign Application Priority Data
Jan. 28, 2021 (JP) 2021-012389

(51) Int. Cl. H10K 59/60; H10K 50/11; H10K 59/12; H10K 59/123; H10K 59/35; H10K 59/40

(52) U.S. Cl. CPC H10K 59/60; H10K 50/11; H10K 59/1201; H10K 59/123; H10K 59/35; H10K 59/40

(57) ABSTRACT

A display device having a function of detecting an object that is in contact with or approaches a display portion is provided. The display device includes a light-emitting element and a light-receiving element. The light-emitting element includes a first pixel electrode, a first light-emitting layer over the first pixel electrode, an intermediate layer over the first light-emitting layer, a second light-emitting layer over the intermediate layer, and a common electrode over the second light-emitting layer. The light-receiving element includes a second pixel electrode, a light-receiving layer over the second pixel electrode, and the common electrode over the light-receiving layer. The first light-emitting layer and the second light-emitting layer have a function of emitting light of the same color.

### TECHNICAL FIELD

One embodiment of the present invention relates to a display device. One embodiment of the present invention relates to a method for manufacturing a display device.

Note that one embodiment of the present invention is not limited to the above technical field. Examples of a technical field of one embodiment of the present invention disclosed in this specification and the like include a semiconductor device, a display device, a light-emitting apparatus, a power storage device, a memory device, an electronic device, a lighting device, an input device, an input/output device, a driving method thereof, and a manufacturing method thereof. A semiconductor device refers to any device that can function by utilizing semiconductor characteristics.

### BACKGROUND ART

In recent years, display devices have been used in a variety of devices such as information terminal devices such as smartphones, tablet terminals, and laptop PCs, television devices, and monitor devices. In addition, display devices have been required to have a variety of functions such as a touch sensor function and a function of capturing images of fingerprints for authentication, in addition to a function of displaying images.

Light-emitting apparatuses including light-emitting elements (also referred to as light-emitting devices) have been developed as display devices, for example. In particular, light-emitting elements (also referred to as EL elements or EL devices) utilizing an electroluminescence (EL) phenomenon have features such as ease of reduction in thickness and weight, high-speed response to an input signal, and driving with a direct-constant voltage source, and have been applied to display devices. For example, Patent Document 1 discloses a flexible light-emitting apparatus to which an organic EL element (also referred to as an organic EL device) is applied.

### REFERENCE

### Patent Document

[Patent Document 1] Japanese Published Patent Application No. 2014-197522

### SUMMARY OF THE INVENTION

### Problems to be Solved by the Invention

An object of one embodiment of the present invention is to provide a display device having a function of detecting an object that is in contact with or approaches a display portion and a manufacturing method thereof. An object of one embodiment of the present invention is to provide a display device having a function of performing authentication and a manufacturing method thereof. An object of one embodiment of the present invention is to provide a display device with a high aperture ratio and a manufacturing method thereof. An object of one embodiment of the present invention is to provide a small display device and a manufacturing method thereof. An object of one embodiment of the present invention is to provide a highly reliable display device and a manufacturing method thereof. An object of one embodiment of the present invention is to provide a novel display device and a manufacturing method thereof.

Note that the description of these objects does not preclude the presence of other objects. Note that in one embodiment of the present invention, there is no need to achieve all the objects. Note that other objects can be derived from the description of the specification, the drawings, the claims, and the like.

### Means for Solving the Problems

One embodiment of the present invention is a display device that includes a light-emitting element and a light-receiving element. The light-emitting element includes a first pixel electrode, a first light-emitting layer over the first pixel electrode, an intermediate layer over the first light-emitting layer, a second light-emitting layer over the intermediate layer, a common layer over the second light-emitting layer, and a common electrode over the common layer. The light-receiving element includes a second pixel electrode, a light-receiving layer over the second pixel electrode, the common layer over the light-receiving layer, and the common electrode over the common layer. In the light-emitting element, the common layer has a function of one of a hole-injection layer and an electron-injection layer. In the light-receiving element, the common layer has a function of one of a hole-transport layer and an electron-transport layer.

Alternatively, in the above embodiment, the first light-emitting layer and the second light-emitting layer may have a function of emitting light of the same color.

Alternatively, in the above embodiment, the display device may further include a first transistor and a second transistor. One of a source and a drain of the first transistor may be electrically connected to the first pixel electrode. One of a source and a drain of the second transistor may be electrically connected to the second pixel electrode. The first transistor and the second transistor may contain silicon or a metal oxide in a channel formation region.

Alternatively, one embodiment of the present invention is a method for manufacturing a display device that includes a first step of forming a first pixel electrode, a second pixel electrode, and a connection electrode; a second step of sequentially depositing a first light-emitting film, an intermediate film, and a second light-emitting film over the first pixel electrode and the second pixel electrode; a third step of forming a first sacrificial film over the second light-emitting film and the connection electrode; a fourth step of exposing the second pixel electrode by etching the first sacrificial film, the second light-emitting film, the intermediate film, and the first light-emitting film and forming a first light-emitting layer over the first pixel electrode, the intermediate layer over the first light-emitting layer, the second light-emitting layer over the intermediate layer, and a first sacrificial layer over the second light-emitting layer and the connection electrode; a fifth step of depositing a light-receiving film over the first sacrificial layer and the second pixel electrode; a sixth step of forming a second sacrificial film over the light-receiving film; a seventh step of forming a light-receiving layer over the second pixel electrode and the second sacrificial layer over the light-receiving layer by etching the second sacrificial film and the light-receiving film; an eighth step of removing the first sacrificial layer and the second sacrificial layer; and a ninth step of forming a common electrode over the second light-emitting layer and the light-receiving layer so that the common electrode includes a region in contact with the connection electrode.

Alternatively, in the above embodiment, the first light-emitting film, the second light-emitting film, and the light-receiving film may be formed by an evaporation method using a shielding mask.

Alternatively, in the above embodiment, the first sacrificial film and the second sacrificial film may contain the same metal film, alloy film, metal oxide film, semiconductor film, or inorganic insulating film. In the fourth step, the first light-emitting film and the second light-emitting film may be etched by dry etching using an etching gas not containing oxygen as a main component. In the eighth step, the first sacrificial layer and the second sacrificial layer may be removed by wet etching using a tetramethyl ammonium hydroxide aqueous solution, diluted hydrofluoric acid, oxalic acid, phosphoric acid, acetic acid, nitric acid, or a mixed solution thereof.

Alternatively, in the above embodiment, the first sacrificial film and the second sacrificial film may contain aluminum oxide.

Alternatively, in the above embodiment, the method for manufacturing a display device may include a tenth step of forming a protective layer over the common electrode after the ninth step.

### Effect of the Invention

According to one embodiment of the present invention, it is possible to provide a display device having a function of detecting an object that is in contact with or approaches a display portion and a manufacturing method thereof. According to one embodiment of the present invention, it is possible to provide a display device having a function of performing authentication and a manufacturing method thereof. According to one embodiment of the present invention, it is possible to provide a display device with a high aperture ratio and a manufacturing method thereof. According to one embodiment of the present invention, it is possible to provide a small display device and a manufacturing method thereof. According to one embodiment of the present invention, it is possible to provide a highly reliable display device and a manufacturing method thereof. According to one embodiment of the present invention, it is possible to provide a novel display device and a manufacturing method thereof.

Note that the description of these effects does not preclude the presence of other effects. Note that one embodiment of the present invention does not necessarily have all of these effects. Note that other effects can be derived from the description of the specification, the drawings, and the claims.

### BRIEF DESCRIPTION OF THE DRAWINGS

FIG. 1A to FIG. 1E are cross-sectional views illustrating structure examples of a display device.

FIG. 1F is a diagram illustrating an example of a captured image.

FIG. 2A and FIG. 2B are cross-sectional views each illustrating a structure example of a display device.

FIG. 3A and FIG. 3B are cross-sectional views each illustrating a structure example of the display device.

FIG. 4 is a cross-sectional view illustrating a structure example of the display device.

FIG. 5A and FIG. 5B are cross-sectional views each illustrating a structure example of the display device.

FIG. 6A to FIG. 6C are cross-sectional views each illustrating a structure example of the display device.

FIG. 7A and FIG. 7B are top views each illustrating a structure example of the display device.

FIG. 8A and FIG. 8B are top views each illustrating a structure example of the display device.

FIG. 9A is a top view illustrating a structure example of the display device. FIG. 9B is a diagram illustrating light-receiving ranges of light-receiving elements.

FIG. 10 is a top view illustrating a structure example of the display device.

FIG. 11A to FIG. 11E are cross-sectional views each illustrating a structure example of the display device.

FIG. 12A to FIG. 12D are cross-sectional views illustrating an example of a method for manufacturing the display device.

FIG. 13A to FIG. 13C are cross-sectional views illustrating the example of a method for manufacturing the display device.

FIG. 14A to FIG. 14D are cross-sectional views illustrating the example of the method for manufacturing the display device.

FIG. 15A to FIG. 15C are cross-sectional views illustrating the example of the method for manufacturing the display device.

FIG. 16 is a perspective view illustrating a structure example of a display device.

FIG. 17 is a cross-sectional view illustrating a structure example of a display device.

FIG. 18 is a cross-sectional view illustrating a structure example of a display device.

FIG. 19 is a cross-sectional view illustrating a structure example of a display device.

FIG. 20 is a cross-sectional view illustrating a structure example of a display device FIG. 21 is a cross-sectional view illustrating a structure example of a display device.

FIG. 22A and FIG. 22B are diagrams each illustrating an example of an electronic device.

FIG. 23A and FIG. 23B are drawings each illustrating an example of an electronic device.

FIG. 24A to FIG. 24E are diagrams each illustrating an example of an electronic device.

### MODE FOR CARRYING OUT THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of embodiments below.

Note that in structures of the present invention described below, the same reference numerals are commonly used for the same portions or portions having similar functions in different drawings, and a repeated description thereof is omitted. Moreover, similar functions are denoted by the same hatching pattern and are not denoted by specific reference numerals in some cases.

Note that in each drawing described in this specification, the size, the layer thickness, or the region of each component is exaggerated for clarity in some cases. Therefore, the size, the layer thickness, or the region is not limited to the illustrated scale.

Note that ordinal numbers such as “first” and “second” in this specification are used in order to avoid confusion among components and do not limit the number of components.

In addition, in this specification and the like, the term “film” and the term “layer” can be interchanged with each other. For example, in some cases, the term “conductive layer” or “insulating layer” can be interchanged with the term “conductive film” or “insulating film.”

Note that in this specification and the like, an EL layer refers to a layer that contains at least a light-emitting substance (also referred to as a light-emitting layer) or a stack including the light-emitting layer provided between a pair of electrodes of a light-emitting element.

In this specification and the like, a display panel that is one embodiment of a display device has a function of displaying (outputting), for example, an image on (to) a display surface. Therefore, the display panel is one embodiment of an output device.

Furthermore, in this specification and the like, a substrate of a display panel to which a connector such as an FPC (Flexible Printed Circuit) or a TCP (Tape Carrier Package) is attached, or a substrate on which an IC is mounted by a COG (Chip On Glass) method or the like is referred to as a display panel module, a display module, or simply a display panel or the like in some cases.

### Embodiment 1

In this embodiment, structure examples of a display device according to one embodiment of the present invention and an example of a method for manufacturing the display device will be described.

The display device according to one embodiment of the present invention includes a display portion where a plurality of pixels arranged in a matrix. The pixel includes a plurality of subpixels, and one light-emitting element (also referred to as light-emitting device) is provided for each subpixel. A plurality of subpixels provided in the same pixel can have a function of emitting light of different colors.

Light-emitting elements each include a pair of electrodes and a light-emitting layer therebetween. The light-emitting elements are preferably organic EL elements (organic electroluminescent elements). Two or more light-emitting elements that emit different colors include light-emitting layers containing different materials. For example, when three kinds of light-emitting elements that emit red (R) light, green (G) light, and blue (B) light are included, a full-color display device can be achieved.

Here, in the case where the light-emitting layers are separately formed between light-emitting elements of different colors, an evaporation method using a shadow mask such as a metal mask is known. However, this method causes a deviation from the designed shape and position of an island-shaped organic film due to various influences such as the accuracy of the metal mask, the positional deviation between the metal mask and a substrate, a warp of the metal mask, and expansion of the outline of a deposited film die to vapor scattering, for example; accordingly, it is difficult to achieve high resolution and high aperture ratio. Therefore, a measure has been taken for pseudo increase in resolution (also referred to pixel density) by employing unique pixel arrangement such as PenTile arrangement, for example.

In one embodiment of the present invention, fine patterning of light-emitting layers is performed without a shadow mask such as a metal mask. This enables further miniaturization of subpixels compared to the case of separately forming light-emitting layers by using a shadow mask and an increase in pixel aperture ratio. Moreover, since light-emitting layers can be formed separately, it is possible to achieve a display device that performs extremely clear display with high contrast and high display quality.

Miniaturization of subpixels enables providing subpixels that do not contribute to display in a pixel. For example, in addition to a subpixel that includes a light-emitting element, a subpixel that includes a light-receiving element (also referred to as a light-receiving device) can be provided in a pixel. Even in such a case, the display device according to one embodiment of the present invention can inhibit a decrease in pixel density. For example, the pixel density can be higher than or equal to 400 ppi, can be higher than or equal to 1000 ppi, can be higher than or equal to 3000 ppi, or can be higher than or equal to 5000 ppi.

A light-receiving element included in the display device according to one embodiment of the present invention has a function of an optical sensor. Thus, the display device according to one embodiment of the present invention can display an image by the light-emitting element and can detect, for example, an object that is in contact with or approaches the display portion by the light-receiving element. In addition, the display device according to one embodiment of the present invention can perform authentication based on the fingerprint of a finger of a user of the display device in the case where the finger is in contact with the display portion, for example.

Providing the light-receiving element in the display portion eliminates the need for attachment of an external sensor to the display device. Thus, the number of components in the display device can be reduced, so that the display device can be made smaller and lightweight.

In addition, in the display device according to one embodiment of the present invention, the light-receiving element can detect light that is emitted from the light-emitting element to be delivered on an object and is reflected by the object. Thus, for example, even in a dark place, the object that is in contact with or approaches the display portion can be detected, and authentication such as fingerprint authentication can be performed.

In this specification and the like, a device manufactured using a metal mask or an FMM (a fine metal mask or a high-resolution metal mask) is sometimes referred to as a device having an MM (metal mask) structure. In addition, in this specification and the like, a device manufactured without using a metal mask or an FMM is sometimes referred to as a device having an MML (metal maskless) structure.

Note that in this specification and the like, a structure in which light-emitting layers in light-emitting elements of respective colors (here, blue (B), green (G), and red (R)) are separately formed or the light-emitting layers are separately patterned is sometimes referred to as an SBS (Side By Side) structure. In addition, in this specification and the like, a light-emitting element capable of emitting white light is sometimes referred to as a white light-emitting element. Note that a combination of a white light-emitting element with a coloring layer (e.g., a color filter) enables a full-color display device.

In addition, light-emitting elements can be roughly classified into a single structure and a tandem structure. A light-emitting element having a single structure includes one light-emitting unit between a pair of electrodes, and the light-emitting unit preferably includes one or more light-emitting layers. To obtain white light emission, two or more light-emitting layers are selected so that emission colors of the light-emitting layers have a relationship of complementary colors. For example, when an emission color of a first light-emitting layer and an emission color of a second light-emitting layer have a relationship of complementary colors, it is possible to obtain a structure where the light-emitting element can emit white light as a whole. The same applies to a light-emitting element including three or more light-emitting layers.

A light-emitting element having a tandem structure includes two or more light-emitting units between a pair of electrodes, and each light-emitting unit preferably includes one or more light-emitting layers. To obtain white light emission, the structure is made so that light from light-emitting layers of the plurality of light-emitting units can be combined to be white light. Note that a structure for obtaining white light emission is similar to that in the single structure. Note that in the light-emitting element having the tandem structure, an intermediate layer such as a charge-generation layer is suitably provided between the plurality of light-emitting units.

Furthermore, when the white light-emitting element (the single structure or the tandem structure) and a light-emitting element having an SBS structure are compared, the light-emitting element having the SBS structure can have lower power consumption than the white light-emitting element. Thus, in the case where the power consumption of the display device is required to be low, the light-emitting element having the SBS structure is suitably used. Meanwhile, in the white light-emitting element, manufacturing cost can be reduced or manufacturing yield can be increased because the manufacturing process of the white light-emitting element is simpler than that of the light-emitting element having the SBS structure.

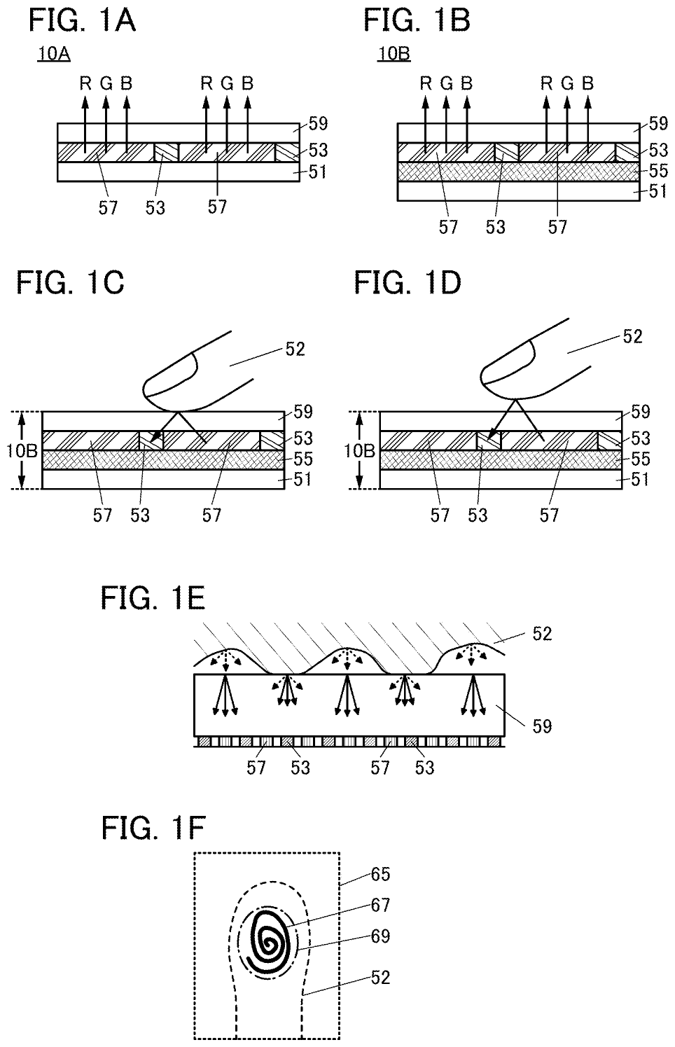

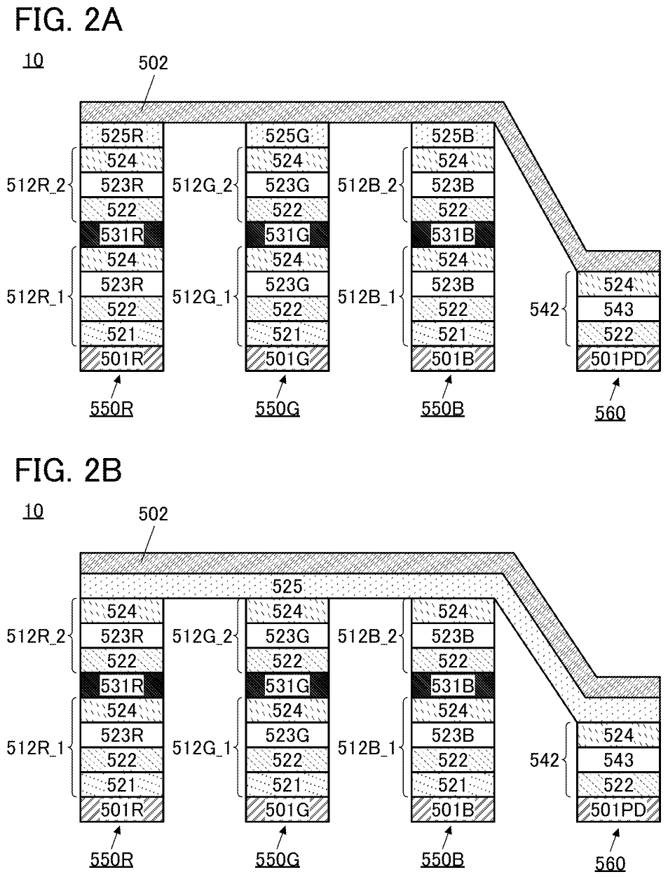

FIG. 1A to FIG. 1E are cross-sectional views illustrating structure examples of the display device according to one embodiment of the present invention.

A display device 10A illustrated in FIG. 1A includes layers 53 each including a light-receiving element and layers 57 each including a light-emitting element between a substrate 51 and a substrate 59.

A display device 10B illustrated in FIG. 1B includes a layer 55 including transistors, the layers 53 each including a light-receiving element, and the layers 57 each including a light-emitting element between the substrate 51 and the substrate 59.

In the display device 10A and the display device 10B, red (R) light, green (G) light, and blue (B) light are emitted from the layers 57 each including a light-emitting element.

In the display device according to one embodiment of the present invention, the plurality of pixels arranged in a matrix are provided in the display portion. One pixel includes one or more subpixels. One subpixel includes one light-emitting element or one light-receiving element. Four subpixels can be included in a pixel, for example. Specifically, for example, one pixel can include light-emitting elements of three colors of R, G, and B and a light-receiving element, or one pixel can include light-emitting elements of three colors of yellow (Y), cyan (C), and magenta (M) and a light-receiving element. Alternatively, five subpixels can be included in a pixel. Specifically, for example, one pixel can include light-emitting elements of four colors of R, G, B, and white (W) and a light-receiving element. Alternatively, one pixel can include light-emitting elements of four colors of R, G, B, and infrared rays (IR) and a light-receiving element. Note that the light-receiving element may be provided in all the pixels or may be provided in some of the pixels. In addition, one pixel may include a plurality of light-receiving elements.

The display device according to one embodiment of the present invention may have a function of detecting an object such as a finger that is in contact with the display device. For example, light emitted from the light-emitting element in the layer 57 including the light-emitting element is reflected by a finger 52 that touches the display device 10B as illustrated in FIG. 1C, and the light-receiving element in the layer 53 including the light-receiving element detects the reflected light. Thus, the touch of the finger 52 on the display device 10B can be detected. In addition, light emitted from the light-emitting element in the layer 57 including the light-emitting element is reflected by the finger 52 that approaches the display device 10B as illustrated in FIG. 1D, and the light-receiving element in the layer 53 including the light-receiving element detects the reflected light. Thus, the approach of the finger 52 on the display device 10B can be detected. In other words, the display device according to one embodiment of the present invention can have a function of a touch sensor (also referred to as a direct touch sensor) or can have a function of a near touch sensor (also referred to as a hover sensor, a hover touch sensor, a contactless sensor, or a touchless sensor).

As described above, for example, in the case where the display device 10B has a function of a near touch sensor, even when the finger 52 does not touch the display device 10B, the finger 52 can be detected when the finger 52 approaches the display device 10B. For example, a structure is preferable in which the display device 10B can detect the finger 52 when a distance between the display device 10B and the finger 52 is more than or equal to 0.1 mm and less than or equal to 300 mm, preferably more than or equal to 3 mm and less than or equal to 50 mm. With this structure, the display device 10B can be operated without a direct touch of the finger 52 on the display device 10B. In other words, the display device 10B can be operated in a contactless (touchless) manner. With the above structure, the display device 10B can have a reduced risk of being dirty or damaged. Furthermore, the display device 10B can be operated with the finger 52 without dirt (e.g., dust, bacteria, a virus, or the like) that might be attached to the display device 10B directly touching the finger 52.

In addition, the display device according to one embodiment of the present invention can have a function of detecting the fingerprint of the finger 52, for example. FIG. 1E schematically illustrates an enlarged view of a contact portion in a state where the finger 52 touches the substrate 59. Furthermore, FIG. 1E illustrates a state where the layers 57 each including a light-emitting element and the layers 53 each including a light-receiving element are alternately arranged.

The fingerprint of the finger 52 is formed of depressions and projections. Therefore, as illustrated in FIG. 1E, the projections of the fingerprint touch the substrate 59.

Reflection of light from a surface or an interface is categorized into regular reflection and diffuse reflection. Regularly reflected light is highly directional light with an angle of reflection equal to the angle of incidence. Diffusely reflected light has low directionality and low angular dependence of intensity. As for regular reflection and diffuse reflection, diffuse reflection components are dominant in the light reflected from the surface of the finger 52. Meanwhile, regular reflection components are dominant in the light reflected from the interface between the substrate 59 and the air.

The intensity of light that is reflected on a contact surface or a non-contact surface between the finger 52 and the substrate 59 and is incident on the layer 53 positioned directly below the contact surface or the non-contact surface is the sum of intensities of regularly reflected light and diffusely reflected light. As described above, regularly reflected light (indicated by solid arrows) is dominant in the depressions of the finger 52 where the finger 52 does not touch the substrate 59, whereas diffusely reflected light (indicated by dashed arrows) from the finger 52 is dominant in the projections where the finger 52 touches the substrate 59. Thus, the intensity of light received by the light-receiving element of the layer 53 positioned directly below the depression is higher than the intensity of light received by the light-receiving element of the layer 53 positioned directly below the projection. Accordingly, an image of the fingerprint of the finger 52 can be captured using the light-receiving element.

In the case where an arrangement interval between the light-receiving elements of the layers 53 is smaller than a distance between two projections of a fingerprint, preferably a distance between a depression and a projection adjacent to each other, a clear fingerprint image can be obtained. A distance between a depression and a projection of a human's fingerprint is generally within a range from 150 μm to 250 μm; thus, the arrangement interval between the light-receiving elements is, for example, less than or equal to 400 μm, preferably less than or equal to 200 μm, further preferably less than or equal to 150 μm, still further preferably less than or equal to 120 μm, yet further preferably less than or equal to 100 μm, yet still further preferably less than or equal to 50 μm. The arrangement interval is preferably as small as possible, and can be more than or equal to 1 μm, more than or equal to 10 μm, or more than or equal to 20 μm, for example.

FIG. 1F is an example of a fingerprint image captured by the display device according to one embodiment of the present invention. In FIG. 1F, the outline of the finger 52 is indicated by a dashed line and the outline of a contact portion 69 is indicated by a dashed-dotted line in a region 65. In the region 65, a high-contrast image of a fingerprint 67 can be captured owing to a difference in the amount of light incident on the light-receiving elements.

As described above, in the display device according to one embodiment of the present invention, the light-receiving element can detect light that is emitted from the light-emitting element to be delivered on the object such as the finger 52 and is reflected by the object such as the finger 52. Thus, for example, even in a dark place, the object that is in contact with or approaches the display portion, for example, can be detected, and authentication such as fingerprint authentication can be performed.

In addition, providing the light-receiving element in the display portion eliminates the need for attachment of an external sensor to the display device. Thus, the number of components in the display device can be reduced, so that the display device can be made smaller and lightweight.

### <Structure Example of Display Device>

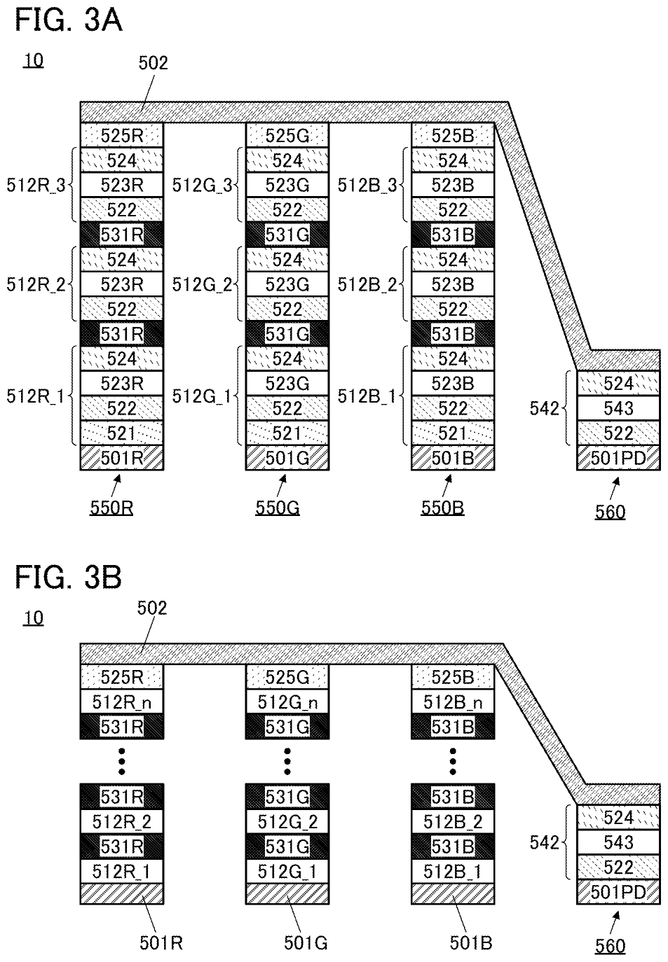

FIG. 2A illustrates a schematic cross-sectional view of a display device 10. The display device 10 includes a light-emitting element 550R that emits red light, a light-emitting element 550G that emits green light, a light-emitting element 550B that emits blue light, and a light-receiving element 560.

The light-emitting element 550R has a structure in which between a pair of electrodes (an electrode 501R and an electrode 502), two light-emitting units 512R (a light-emitting unit 512R_1 and a light-emitting unit 512R_2) are stacked with an intermediate layer 531R therebetween. Similarly, the light-emitting element 550G has a structure in which between a pair of electrodes (an electrode 501G and the electrode 502), two light-emitting units 512G (a light-emitting unit 512G_1 and a light-emitting unit 512G_2) are stacked with an intermediate layer 531G therebetween. Furthermore, the light-emitting element 550B has a structure in which between a pair of electrodes (an electrode 501B and the electrode 502), two light-emitting units 512B (a light-emitting unit 512B_1 and a light-emitting unit 512B_2) are stacked with an intermediate layer 531B therebetween.

In the light-receiving element 560, a light-receiving unit 542 is provided between a pair of electrodes (an electrode 501PD and the electrode 502).

In this specification and the like, in the case where a common matter between the display device 10A and the display device 10B is described or in the case where it is not necessary to differentiate between these, for example, the display device 10A and the display device 10B are simply referred to as a “display device 10.” That is, the structure and the like of the display device 10 can be applied to both the display device 10A illustrated in FIG. 1A and the display device 10B illustrated in FIG. 1B. The same applies to other elements.

An electrode 501 functions as a pixel electrode, which is provided for each light-emitting element 550 and each light-receiving element 560. The electrode 502 functions as a common electrode, which is commonly provided for a plurality of light-emitting elements 550 and the light-receiving element 560.

The light-emitting unit 512R_1 includes a layer 521, a layer 522, a light-emitting layer 523R, a layer 524, and the like. In addition, the light-emitting unit 512R_2 includes the layer 522, the light-emitting layer 523R, the layer 524, and the like. Furthermore, the light-emitting element 550R includes, for example, a layer 525R between the light-emitting unit 512R_2 and the electrode 502. Note that the layer 525R can also be regarded as part of the light-emitting unit 512R_2.

The layer 521 includes, for example, a layer containing a substance with a high hole-injection property (a hole-injection layer). The layer 522 includes, for example, a layer containing a substance with a high hole-transport property (a hole-transport layer). The layer 524 includes, for example, a layer containing a substance with a high electron-transport property (an electron-transport layer). A layer 525 includes, for example, a layer containing a substance with a high electron-injection property (an electron-injection layer).

Alternatively, the layer 521 may include an electron-injection layer, the layer 522 may include an electron-transport layer, the layer 524 may include a hole-transport layer, and the layer 525 may include a hole-injection layer.

Note that the layer 522, the light-emitting layer 523R, and the layer 524 may have the same structure (material, film thickness, and the like) or may have different structures from the light-emitting unit 512R_1 and the light-emitting unit 512R_2.

Note that FIG. 2A explicitly illustrates the layer 521 and the layer 522 separately; however, one embodiment of the present invention is not limited thereto. For example, the layer 522 may be omitted when the layer 521 has functions of both a hole-injection layer and a hole-transport layer or the layer 521 has functions of both an electron-injection layer and an electron-transport layer.

Furthermore, the intermediate layer 531R has a function of injecting electrons into one of the light-emitting unit 512R_1 and the light-emitting unit 512R_2 and injecting holes to the other of the light-emitting unit 512R_1 and the light-emitting unit 512R_2 when voltage is applied between the electrode 501 and the electrode 502. The intermediate layer 531R can also be referred to as a charge-generation layer.

The light-emitting unit 512R is explicitly described in the above description, and a structure similar to the light-emitting unit 512R can be employed for the light-emitting unit 512G and the light-emitting unit 512B.

Note that the light-emitting layer 523R included in the light-emitting element 550R includes a light-emitting substance that emits red light, the light-emitting layer 523G included in the light-emitting element 550G includes a light-emitting substance that emits green light, and the light-emitting layer 523B included in the light-emitting element 550B includes a light-emitting substance that emits blue light. Note that the light-emitting element 550G and the light-emitting element 550B have a structure in which the light-emitting layer 523R included in the light-emitting element 550R is replaced with the light-emitting layer 523G and the light-emitting layer 523B, respectively, and the other components are similar to those of the light-emitting element 550R.

Note that the layer 521, the layer 522, the layer 524, and the layer 525 may have the same structure (material, film thickness, and the like) or may have different structures from the light-emitting elements of respective colors.

A structure where a plurality of light-emitting units are connected in series with an intermediate layer 531 therebetween like the light-emitting element 550R, the light-emitting element 550G, and the light-emitting element 550B is referred to as a tandem structure in this specification and the like. On the other hand, a structure where one light-emitting unit is included between a pair of electrodes is referred to as a single structure. Note that in this specification and the like, such a structure is referred to as a tandem structure; however, without being limited to this, a tandem structure may be referred to as a stack structure, for example. Note that the tandem structure enables a light-emitting element to emit light at high luminance. Furthermore, the tandem structure allows the amount of current needed for obtaining the same luminance to be reduced as compared to the case of using the single structure, and thus can improve the reliability of the display device.

In addition, a structure where light-emitting layers are separately formed for light-emitting elements like the light-emitting element 550R, the light-emitting element 550G, and the light-emitting element 550B is sometimes referred to as an SBS structure. The SBS structure can optimize materials and structures of light-emitting elements and thus increases the degree of freedom in selecting materials and structures, so that the luminance and the reliability can be easily improved.

The structure of the display device 10 according to one embodiment of the present invention is a tandem structure and can also be referred to as an SBS structure. Thus, the display device 10 according to one embodiment of the present invention takes advantages of both the tandem structure and the SBS structure. Note that the structure of the display device 10 according to one embodiment of the present invention is a structure where two light-emitting units are formed in series as illustrated in FIG. 2A; therefore, such a structure may be referred to as a two-unit tandem structure. In addition, a two-unit tandem structure illustrated in FIG. 2A is a structure where a second light-emitting unit including a red light-emitting layer is stacked over a first light-emitting unit including a red light-emitting layer. Similarly, the two-unit tandem structure illustrated in FIG. 2A is a structure where a second light-emitting unit including a green light-emitting layer is stacked over a first light-emitting unit including a green light-emitting layer and a second light-emitting unit including a blue light-emitting layer is stacked over a first light-emitting unit including a blue light-emitting layer.

The light-receiving unit 542 included in the light-receiving element 560 includes the layer 522, a light-receiving layer 543, the layer 524, and the like. The light-receiving unit 542 can be configured not to include a hole-injection layer and an electron-injection layer. The layer 522 and the layer 524 included in the light-receiving unit 542 may have the same structure (material, film thickness, and the like) or may have different structures from the layer 522 and the layer 524 included in a light-emitting unit 512.

FIG. 2B is a modification example of the display device 10 illustrated in FIG. 2A. The display device 10 illustrated in FIG. 2B is an example in which a layer 525 is commonly provided for the light-emitting elements 550 and the light-receiving elements 560 like the electrode 502. At this time, the layer 525 can be referred to as a common layer. By providing one or more common layers for the light-emitting elements 550 and the light-receiving elements 560 in this manner, the manufacturing process can be simplified, which results in a reduction in manufacturing cost.

Here, for the light-emitting element 550, the layer 525 has a function of an electron-injection layer. Meanwhile, for the light-receiving element 560, the layer 525 has a function of an electron-transport layer. Therefore, in the case where the display device 10 has the structure illustrated in FIG. 2B, the light-receiving unit 542 is not necessarily provided with the layer 524 that has a function of an electron-transport layer.

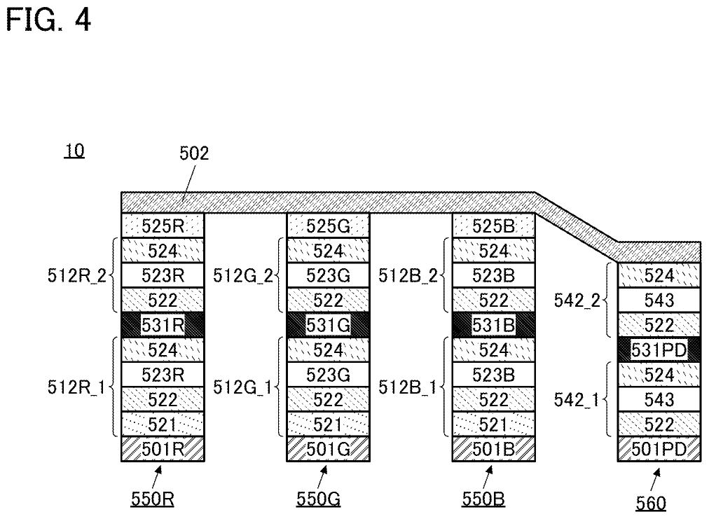

The display device 10 illustrated in FIG. 3A is an example in which three light-emitting units are stacked. In the light-emitting element 550R in FIG. 3A, a light-emitting unit 512R_3 is further stacked over the light-emitting unit 512R_2 with another intermediate layer 531R therebetween. The light-emitting unit 512R_3 has a structure similar to that of the light-emitting unit 512R_2. The same applies to a light-emitting unit 512G_3 included in the light-emitting element 550G and a light-emitting unit 512B_3 included in the light-emitting element 550B.

FIG. 3B illustrates an example in which n light-emitting units (n is an integer greater than or equal to 2) are stacked.

When the number of stacked light-emitting units is increased in this manner, luminance obtained from the light-emitting element with the same amount of current can be increased in accordance with the number of stacked layers. Moreover, increasing the number of stacked light-emitting units can reduce current that is necessary for obtaining the same luminance; thus, power consumption of the light-emitting element can be reduced in accordance with the number of stacked layers.

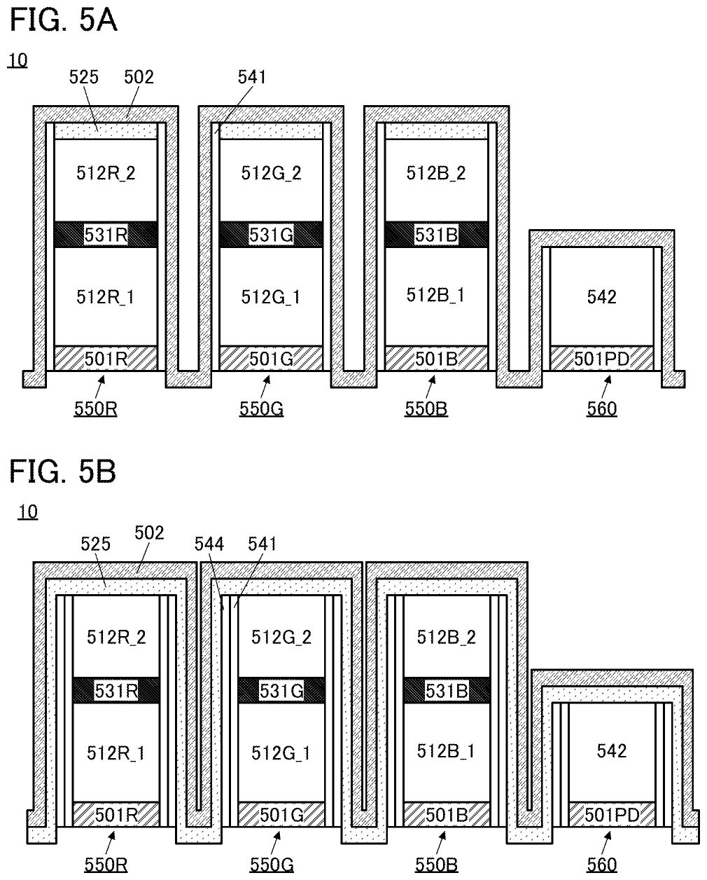

FIG. 4 is a modification example of the display device 10 illustrated in FIG. 2A. The display device 10 illustrated in FIG. 4 is an example in which the light-receiving element 560 includes two light-receiving units 542 (the light-receiving unit 542_1 and the light-receiving unit 542_2). The light-receiving unit 542_1 and the light-receiving unit 542_2 are stacked with an intermediate layer 531PD therebetween. Note that although FIG. 4 illustrates the structure where the two light-receiving units are stacked, one embodiment of the present invention is not limited thereto. For example, three or more light-receiving units may be stacked.

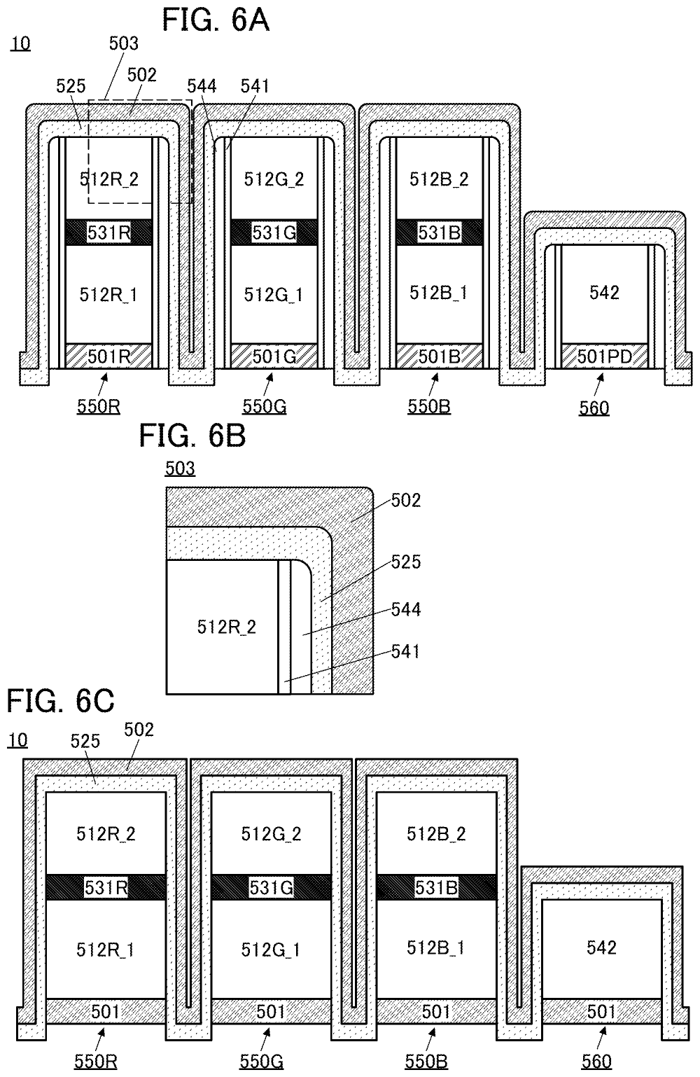

The display device 10 illustrated in FIG. 5A is an example in which two adjacent light-emitting elements and the like are apart from each other and the electrode 502 is provided along a side surface of the light-emitting unit 512, a side surface of the intermediate layer 531, a side surface of the light-receiving unit 542, and the like.

Here, when the intermediate layer 531 is in contact with the electrode 502, electrical short-circuit occurs in some cases. Therefore, the intermediate layer 531 and the electrode 502 are preferably insulated from each other.

FIG. 5A illustrates an example in which an insulating layer 541 is provided to cover the electrode 501, a side surface of each light-emitting unit 512, the side surface of the intermediate layer 531, and the side surface of the light-receiving unit 542. The insulating layer 541 can be referred to as a sidewall protective layer, a sidewall insulating film, or the like. When the insulating layer 541 is provided, the intermediate layer 531 and the electrode 502 can be electrically insulated from each other.

In addition, the side surface of each light-emitting unit 512, the side surface of the intermediate layer 531, and the side surface of the light-receiving unit 542 is preferably perpendicular or substantially perpendicular to a formation surface. For example, an angle between the formation surface and these side surfaces is preferably greater than or equal to 60° and less than or equal to 90°.

FIG. 5B illustrates an example in which the layer 525 and the electrode 502 are provided along the side surface of the light-emitting unit 512, the side surface of the intermediate layer 531, and the side surface of the light-receiving unit 542. In addition, a two-layer structure of the insulating layer 541 and an insulating layer 544 is employed as a sidewall protective layer.

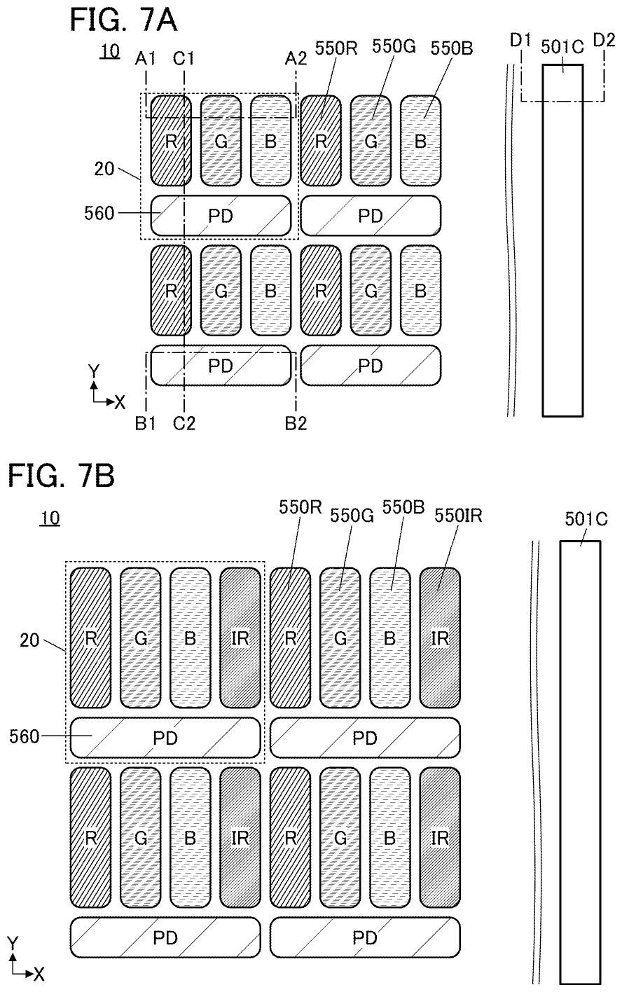

In addition, FIG. 6A is a modification example of FIG. 5B. Furthermore, FIG. 6B is an enlarged view of a region 503 illustrated in FIG. 6A. The shape of an end portion of the insulating layer 544 differs between FIG. 6A and FIG. 5B. In addition, the shape of the end portion of the insulating layer 544 differs between FIG. 6A and FIG. 5B and the layer 525 and the electrode 502 are provided along the shape of the insulating layer 544; thus, the shapes of the layer 525 and the electrode 502 also differ between FIG. 6A and FIG. 5B. Furthermore, the thicknesses of the insulating layer 541 and the insulating layer 544 differ between FIG. 6A and FIG. 5B. FIG. 6A has a structure in which the thickness of the insulating layer 544 is larger than the thickness of the insulating layer 541. The shape of the end portion of the insulating layer 544 is a rounded shape as illustrated in FIG. 6B. For example, in the case where a dry etching method is used for forming the insulating layer 544 and an upper portion of the insulating layer 544 is etched by anisotropic etching, the end portion of the insulating layer 544 is made into a rounded shape as illustrated in FIG. 6B. The shape of the end portion of the insulating layer 544 is suitably made into a rounded shape because coverage with the layer 525 and the electrode 502 is increased. Moreover, in the case where the thickness of the insulating layer 544 is made larger than the thickness of the insulating layer 541 as illustrated in FIG. 6A and FIG. 6B, the shape of the end portion is sometimes easily made into a rounded shape.

With the insulating layer 541 and the insulating layer 544 functioning as a sidewall protective layer, electrical short-circuit between the electrode 502 and the intermediate layer 531 can be prevented. In addition, when the insulating layer 541 and the insulating layer 544 cover side surfaces of the electrode 501, electrical short-circuit between the electrode 501 and the electrode 502 can be prevented. Accordingly, electrical short-circuit in corner portions that are positioned at four corners of the light-emitting element can be prevented.

An organic insulating film is preferably used for each of the insulating layer 541 and the insulating layer 544. For example, it is possible to use a film of an oxide or a nitride such as silicon oxide, silicon oxynitride, silicon nitride oxide, silicon nitride, aluminum oxide, aluminum oxynitride, or hafnium oxide. Alternatively, yttrium oxide, zirconium oxide, gallium oxide, tantalum oxide, magnesium oxide, lanthanum oxide, cerium oxide, neodymium oxide, or the like may be used.

The insulating layer 541 and the insulating layer 544 can be formed by, for example, a variety of deposition methods such as a sputtering method, an evaporation method, a chemical vapor deposition (CVD) method, and an atomic layer deposition (ALD) method. In particular, an ALD method gives small deposition damage to layers to be formed; thus, the insulating layer 541 that is directly formed on the light-emitting unit and the intermediate layer 531 is preferably formed by the ALD method. Furthermore, at this time, the insulating layer 544 is preferably formed by a sputtering method because productivity can be increased.

For example, an aluminum oxide film formed by an ALD method can be used for the insulating layer 541, and a silicon nitride film formed by a sputtering method can be used for the insulating layer 544.

In addition, either one or both the insulating layer 541 and the insulating layer 544 suitably have a function of a barrier insulating film against at least one of water and oxygen. Alternatively, either one or both the insulating layer 541 and the insulating layer 544 suitably have a function of inhibiting diffusion of at least one of water and oxygen. Alternatively, either one or both the insulating layer 541 and the insulating layer 544 suitably have a function of capturing or fixing (also referred to as gettering) at least one of water and oxygen.

Note that in this specification and the like, a barrier insulating film refers to an insulating film having a barrier property. In addition, a barrier property in this specification and the like means a function of inhibiting diffusion of a particular substance (also referred to as having low permeability). Furthermore, a barrier property in this specification and the like means a function of capturing and fixing (also referred to as gettering) a particular substance.

When either one or both the insulating layer 541 and the insulating layer 544 have a function of the barrier insulating film or a gettering function, entry of impurities (typically, water or oxygen) that would diffuse into the light-emitting elements from the outside can be inhibited. With such a structure, a highly reliable display device can be provided.

Note that as illustrated in FIG. 6C, the display device 10 may be configured not to include the insulating layer 541 and the insulating layer 544 functioning as a sidewall protective layer. In FIG. 6C, the layer 525 is provided in contact with the side surface of each light-emitting unit 512, the side surface of the intermediate layer 531, and the side surface of the light-receiving unit 542.

### <Structure Example of Light-Emitting Element>

The emission color of the light-emitting elements can be red, green, blue, cyan, magenta, yellow, white, or the like depending on materials that constitute a light-emitting layer 523 and the like. Furthermore, color purity can be further increased when the light-emitting element has a microcavity structure.

In the case where the light-emitting element emits white light, the light-emitting layer preferably contains two or more kinds of light-emitting substances. To obtain white light emission, two or more kinds of light-emitting substances are selected so that their emission colors have a relationship of complementary colors. For example, when the emission color of a first light-emitting layer and the emission color of a second light-emitting layer have a relationship of complementary colors, it is possible to obtain the light-emitting element that emits white light as a whole. The same applies to a light-emitting element including three or more light-emitting layers.

The light-emitting layer preferably contains two or more kinds of light-emitting substances that emit light of red (R), green (G), blue (B), yellow (Y), orange (O), and the like.

Here, a specific structure example of each layer of a light-emitting element will be described.

The light-emitting element includes at least the light-emitting layer. The light-emitting element may further include, as a layer other than the light-emitting layer, a layer containing a substance with a high hole-injection property, a substance with a high hole-transport property, a hole-blocking material, a substance with a high electron-transport property, an electron-blocking material, a substance with a high electron-injection property, a substance with a bipolar property (a substance with a high electron-transport property and a high hole-transport property), or the like.

Either a low molecular compound or a high molecular compound can be used for the light-emitting element, and an inorganic compound may also be contained. Each of the layers included in the light-emitting element can be formed by an evaporation method (including a vacuum evaporation method), a transfer method, a printing method, an inkjet method, a coating method, or the like.

For example, the light-emitting element can include one or more of a hole-injection layer, a hole-transport layer, a hole-blocking layer, an electron-blocking layer, an electron-transport layer, and an electron-injection layer.

The hole-injection layer is a layer injecting holes from an anode to the hole-transport layer, and a layer containing a material with a high hole-injection property. Examples of the material with a high hole-injection property include an aromatic amine compound, a composite material containing a hole-transport material and an acceptor material (an electron-accepting material), and the like.

The hole-transport layer is a layer transporting holes, which are injected from the anode by the hole-injection layer, to the light-emitting layer. The hole-transport layer is a layer containing a hole-transport material. As the hole-transport material, a substance having a hole mobility greater than or equal to 1×10⁻⁶ cm²/Vs is preferable. Note that other substances can also be used as long as they have a property of transporting more holes than electrons. As the hole-transport material, a material with a high hole-transport property, such as a π-electron rich heteroaromatic compound (e.g., a carbazole derivative, a thiophene derivative, a furan derivative, or the like) or an aromatic amine (a compound having an aromatic amine skeleton), is preferable.

The electron-transport layer is a layer transporting electrons, which are injected from a cathode by the electron-injection layer, to the light-emitting layer. The electron-transport layer is a layer containing an electron-transport material. As the electron-transport material, a substance having an electron mobility greater than or equal to 1×10⁻⁶ cm²/Vs is preferable. Note that other substances can also be used as long as they have a property of transporting more electrons than holes. As the electron-transport material, it is possible to use a material with a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a π-electron deficient heteroaromatic compound such as a nitrogen-containing heteroaromatic compound.

The electron-injection layer is a layer injecting electrons from a cathode to the electron-transport layer and a layer containing a material with a high electron-injection property. As the material with a high electron-injection property, an alkali metal, an alkaline earth metal, or a compound thereof can be used. As the material with a high electron-injection property, a composite material containing an electron-transport material and a donor material (an electron-donating material) can also be used.

For the electron-injection layer, it is possible to use, for example, an alkali metal, an alkaline earth metal, or a compound thereof, such as lithium, cesium, ytterbium, lithium fluoride (LiF), cesium fluoride (CsF), calcium fluoride (CaF_{X}, where X is a given number), 8-(quinolinolato)lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), lithium oxide (LiOₓ), or cesium carbonate. In addition, the electron-injection layer may have a stacked-layer structure of two or more layers. For example, it is possible to employ a structure where lithium fluoride is used for a first layer and ytterbium is used for a second layer as the stacked-layer structure.

Alternatively, an electron-transport material may be used for the electron-injection layer. For example, a compound having an unshared electron pair and an electron deficient heteroaromatic ring can be used for the electron-transport material. Specifically, a compound having at least one of a pyridine ring, a diazine ring (a pyrimidine ring, a pyrazine ring, and a pyridazine ring), and a triazine ring can be used.

Note that the lowest unoccupied molecular orbital (LUMO) of the organic compound having an unshared electron pair is preferably greater than or equal to −3.6 eV and less than or equal to −2.3 eV. In addition, in general, the highest occupied molecular orbital (HOMO) level and the LUMO level of an organic compound can be estimated by cyclic voltammetry (CV), photoelectron spectroscopy, optical absorption spectroscopy, inverse photoelectron spectroscopy, or the like.

For example, 4,7-diphenyl-1,10-phenanthroline (abbreviation: BPhen), 2,9-bis(naphthalen-2-yl)-4,7-diphenyl-1,10-phenanthroline (abbreviation: NBPhen), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPyTz), or the like can be used for the organic compound having an unshared electron pair. Note that NBPhen has a higher glass transition temperature (Tg) than BPhen and thus has high heat resistance.

The light-emitting layer is a layer containing a light-emitting substance. The light-emitting layer can include one or more kinds of light-emitting substances. As the light-emitting substance, a substance that exhibits an emission color of blue, purple, bluish purple, green, yellowish green, yellow, orange, red, or the like is used as appropriate. Alternatively, as the light-emitting substance, a substance that emits near-infrared light can be used.

Examples of the light-emitting substance include a fluorescent material, a phosphorescent material, a TADF material, a quantum dot material, and the like.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, a naphthalene derivative, and the like.

Examples of the phosphorescent material include an organometallic complex (in particular, an iridium complex) having a 4H-triazole skeleton, a 1H-triazole skeleton, an imidazole skeleton, a pyrimidine skeleton, a pyrazine skeleton, or a pyridine skeleton; an organometallic complex (in particular, an iridium complex) having a phenylpyridine derivative including an electron-withdrawing group as a ligand; a platinum complex; a rare earth metal complex; and the like.

The light-emitting layer may contain one or more kinds of organic compounds (a host material, an assist material, and the like) in addition to the light-emitting substance (a guest material). As one or more kinds of organic compounds, one or both of the hole-transport material and the electron-transport material can be used. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. Such a structure makes it possible to efficiently obtain light emission using ExTET (Exciplex-Triplet Energy Transfer), which is energy transfer from an exciplex to a light-emitting substance (a phosphorescent material). When a combination of materials is selected to form an exciplex that exhibits light emission whose wavelength is to be overlapped with the wavelength of the lowest-energy-side absorption band of the light-emitting substance, energy can be transferred smoothly and light emission can be obtained efficiently. With this structure, the high efficiency, low-voltage driving, and long lifetime of the light-emitting element can be achieved at the same time.

For example, a material that can be employed for the electron-injection layer, such as lithium, can be suitably used for the intermediate layer. Alternatively, as another example, a material that can be employed for the hole-injection layer can be suitably used for the intermediate layer. Alternatively, a layer that includes a hole-transport material and an acceptor material (an electron-accepting material) can be suitably used for the intermediate layer. Alternatively, a layer that includes an electron-transport material and a donor material can be suitably used for the intermediate layer. Forming the intermediate layer with such a layer can inhibit an increase in drive voltage in the case of stacking light-emitting units.

Note that there is no particular limitation on the light-emitting material of the light-emitting layer in the display device 10 illustrated in FIG. 2A. For example, the display device 10 illustrated in FIG. 2A has a structure where the light-emitting layer 523R included in the light-emitting unit 512R_1 contains a phosphorescent material, the light-emitting layer 523R included in the light-emitting unit 512R_2 contains a phosphorescent material, the light-emitting layer 523G included in the light-emitting unit 512G_1 contains a fluorescent material, the light-emitting layer 523G included in the light-emitting unit 512G_2 contains a fluorescent material, the light-emitting layer 523B included in the light-emitting unit 512B_1 contains a fluorescent material, and the light-emitting layer 523B included in the light-emitting layer 523B included in the light-emitting unit 512B_2 contains a fluorescent material.

Alternatively, the display device 10 illustrated in FIG. 2A has a structure where the light-emitting layer 523R included in the light-emitting unit 512R_1 contains a phosphorescent material, the light-emitting layer 523R included in the light-emitting unit 512R_2 contains a phosphorescent material, the light-emitting layer 523G included in the light-emitting unit 512G_1 contains a phosphorescent material, the light-emitting layer 523G included in the light-emitting unit 512G_2 contains a phosphorescent material, the light-emitting layer 523B included in the light-emitting unit 512B_1 contains a fluorescent material, and the light-emitting layer 523B included in the light-emitting layer 523B included in the light-emitting unit 512B_2 contains a fluorescent material.

Note that in the display device according to one embodiment of the present invention, a structure where all the light-emitting layers in the display device 10 illustrated in FIG. 2A each contain a fluorescent material or a structure where all the light-emitting layers in the display device 10 illustrated in FIG. 2A each contain a phosphorescent material may be employed.

Alternatively, in the display device according to one embodiment of the present invention, the display device 10 illustrated in FIG. 2A may employ a structure where the light-emitting layer 523R included in the light-emitting unit 512R_1 contains a phosphorescent material and the light-emitting layer 523R included in the light-emitting unit 512R_2 contains a fluorescent material or a structure where the light-emitting layer 523R included in the light-emitting unit 512R_1 contains a fluorescent material and the light-emitting layer 523R included in the light-emitting unit 512R_2 contains a phosphorescent material, that is, a structure where a light-emitting material used for a light-emitting layer in a first stage is different from a light-emitting material used for a light-emitting layer in a second stage. Note that although the light-emitting unit 512R_1 and the light-emitting unit 512R_2 are explicitly described here, a structure similar to the light-emitting unit 512R_1 and the light-emitting unit 512R_2 can also be employed for the light-emitting unit 512G_1 and the light-emitting unit 512G_2, and the light-emitting unit 512B_1 and the light-emitting unit 512B_2.

### <Structure Example of Light-Receiving Element>

The light-receiving layer 543 included in the light-receiving element 560 contains a semiconductor. Examples of the semiconductor include an inorganic semiconductor such as silicon and an organic semiconductor including an organic compound. This embodiment illustrates an example in which an organic semiconductor is used as the semiconductor included in the light-receiving layer 543. The use of an organic semiconductor is preferable because the light-emitting layer 523 and the light-receiving layer 543 can be formed by the same method (e.g., a vacuum evaporation method) and thus a common manufacturing apparatus can be used.

Examples of an n-type semiconductor material contained in the light-receiving layer 543 include electron-accepting organic semiconductor materials such as fullerene (e.g., C₆₀, C₇₀, or the like) and a fullerene derivative. Fullerene has a soccer ball-like shape, which is energetically stable. Both the HOMO level and the LUMO level of fullerene are deep (low). Having a deep LUMO level, fullerene has an extremely high electron-accepting property (acceptor property). When π-electron conjugation (resonance) spreads in a plane as in benzene, an electron-donating property (donor property) usually increases. However, since fullerene has a spherical shape, fullerene has a high electron-accepting property even when π-electrons widely spread. The high electron-accepting property efficiently causes rapid charge separation and is useful for a light-receiving element. Both C₆₀ and C₇₀ have a wide absorption band in a visible light region, and C₇₀ is particularly preferable because of having a larger π-electron conjugation system and a wider absorption band in a long wavelength region than C₆₀. Other examples of the fullerene derivative include [6,6]-Phenyl-C71-butyric acid methyl ester (abbreviation: PC70BM), [6,6]-Phenyl-C61-butyric acid methyl ester (abbreviation: PC60BM), 1′,1″,4′,4″-Tetrahydro-di[1,4]methanonaphthaleno[1,2:2′,3′,56,60:2″,3″ ][5,6]fullerene-C60 (abbreviation: ICBA), and the like.

Other examples of the n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, a quinone derivative, and the like.

Examples of a p-type semiconductor material contained in the light-receiving layer 543 include electron-donating organic semiconductor materials such as copper(II) phthalocyanine (CuPc), tetraphenyldibenzoperiflanthene (DBP), zinc phthalocyanine (ZnPc), tin phthalocyanine (SnPc), and quinacridone.

Other examples of the p-type semiconductor material include a carbazole derivative, a thiophene derivative, a furan derivative, a compound having an aromatic amine skeleton, and the like. Furthermore, other examples of the p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a polyphenylene vinylene derivative, a polyparaphenylene derivative, a polyfluorene derivative, a polyvinylcarbazole derivative, a polythiophene derivative, and the like.

The HOMO level of the electron-donating organic semiconductor material is preferably shallower (higher) than the HOMO level of the electron-accepting organic semiconductor material. The LUMO level of the electron-donating organic semiconductor material is preferably shallower (higher) than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules of similar shapes tend to aggregate, and aggregated molecules of the same kind, which have molecular orbital energy levels close to each other, can improve a carrier-transport property.

For example, the light-receiving layer 543 is preferably formed through co-evaporation of an n-type semiconductor and a p-type semiconductor. Alternatively, the light-receiving layer 543 may be formed by stacking an n-type semiconductor and a p-type semiconductor.

### <Top-View Structure Example of Display Device>

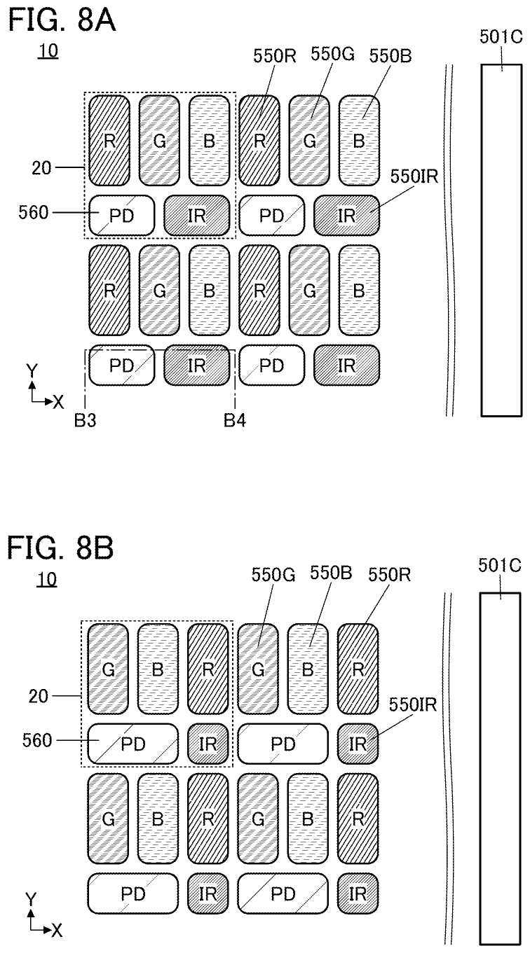

FIG. 7A is a schematic top view illustrating a structure example of the display device 10. The display device 10 includes a plurality of light-emitting elements 550R that emit red light, a plurality of light-emitting elements 550G that emit green light, a plurality of light-emitting elements 550B that emit blue light, and a plurality of light-receiving elements 560. In FIG. 7A, light-emitting regions of the light-emitting elements 550 are denoted by R, G, and B to easily differentiate the light-emitting elements 550. In addition, light-receiving regions of the light-receiving elements 560 are denoted by PD.

The light-emitting elements 550R, the light-emitting elements 550G, the light-emitting elements 550B, and the light-receiving elements 560 are arranged in a matrix. FIG. 7A illustrates an example where the light-emitting elements 550R, the light-emitting elements 550G, and the light-emitting elements 550B are arranged in an X direction and the light-receiving elements 560 are arranged thereunder. FIG. 7A also illustrates a structure example where the light-emitting elements 550 that emit light of the same color are arranged in a Y direction intersecting the X direction. In the display device 10 illustrated in FIG. 7A, a pixel 20 can be composed of a subpixel including the light-emitting element 550R, a subpixel including the light-emitting element 550G, and a subpixel including the light-emitting element 550B, which are arranged in the X direction, and a subpixel including the light-receiving element 560 provided under the subpixels, for example.

FIG. 7A illustrates a connection electrode 501C. The connection electrode 501C is provided outside a display portion where the light-emitting elements 550 and the light-receiving elements 560 are arranged.

The connection electrode 501C can be provided along the outer periphery of the display portion. For example, the connection electrode 501C may be provided along one side of the outer periphery of the display portion or may be provided across two or more sides of the outer periphery of the display portion. That is, when the display portion has a rectangular top surface, the top surface of the connection electrode 501C can have a band shape, an L shape, a square bracket shape, a frame-like shape, or the like.

FIG. 7B is a schematic top view illustrating a structure example of the display device 10 and is a modification example of the display device 10 illustrated in FIG. 7A. The display device 10 illustrated in FIG. 7B differs from the display device 10 illustrated in FIG. 7A in that light-emitting elements 550IR that emit infrared light are included. The light-emitting elements 550IR can emit near-infrared light (light with a wavelength of greater than or equal to 750 nm and less than or equal to 1300 nm), for example.

In the example illustrated in FIG. 7B, the light-emitting elements 550IR as well as the light-emitting elements 550R, the light-emitting elements 550G, and the light-emitting elements 550B are arranged in the X direction, and the light-receiving elements 560 are arranged thereunder. In addition, the light-receiving elements 560 have a function of detecting infrared light.

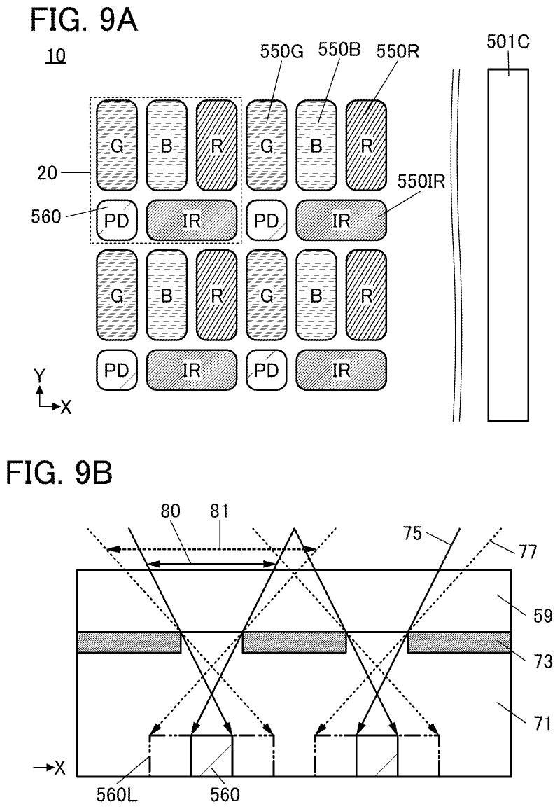

FIG. 8A is a schematic top view illustrating a structure example of the display device 10 and is a modification example of the display device 10 illustrated in FIG. 7B. The display device 10 illustrated in FIG. 8A differs from the display device 10 illustrated in FIG. 7B in that the light-receiving elements 560 and the light-emitting elements 550IR are alternately arranged in the X direction.

In the display device 10 illustrated in FIG. 8A, the light-emitting element 550R, the light-emitting element 550G, and the light-emitting element 550B are arranged in a row different from the row of the light-emitting element 550IR. Thus, the light-emitting element 550R, the light-emitting element 550G, and the light-emitting element 550B can have larger widths (larger lengths in the X direction), so that the luminance of light emitted from the pixel 20 can be increased.

FIG. 8B is a schematic top view illustrating a structure example of the display device 10 and is a modification example of the display device 10 illustrated in FIG. 8A. The display device 10 illustrated in FIG. 8B differs from the display device 10 illustrated in FIG. 8A in that the light-emitting elements 550 are arranged in the X direction in the order of G, B, and R instead of the order of R, G, and B. The display device 10 illustrated in FIG. 8B differs from the display device 10 illustrated in FIG. 8A also in that the light-receiving element 560 is provided below the light-emitting element 550G and the light-emitting element 550B and the light-emitting element 550IR is provided below the light-emitting element 550R.

The area occupied by the light-receiving element 560 in the display device 10 illustrated in FIG. 8B is larger than the area occupied by the light-receiving element 560 in the display device 10 illustrated in FIG. 8A. Accordingly, the light detection sensitivity of the light-receiving element 560 can be increased. Therefore, for example, in the case where the display device 10 has a function of a touch sensor or a near touch sensor, an object that is in contact with or approaches the display device 10 can be detected with high accuracy. In particular, in the case where the display device 10 has a function of a near touch sensor, the light detection accuracy of the light-receiving element 560 has great influence on the detection accuracy of the object; thus, the area occupied by the light-receiving element 560 is preferably made large.

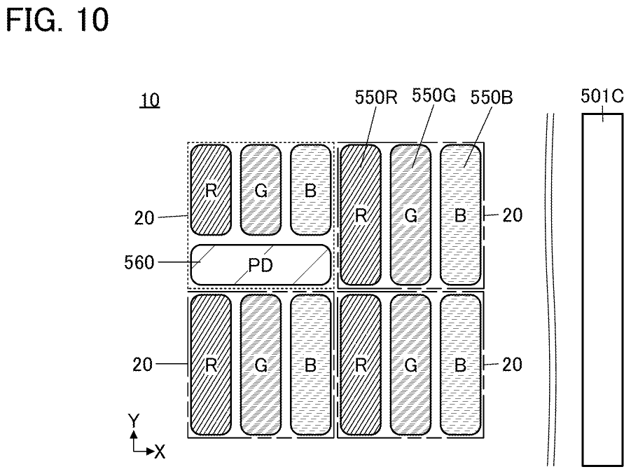

FIG. 9A is a schematic top view illustrating a structure example of the display device 10 and is a modification example of the display device 10 illustrated in FIG. 8B. The display device 10 illustrated in FIG. 9A differs from the display device 10 illustrated in FIG. 8B in that the light-receiving element 560 is provided below the light-emitting element 550G and the light-emitting element 550IR is provided below the light-emitting element 550B and the light-emitting element 550R.

The area occupied by the light-receiving element 560 in the display device 10 illustrated in FIG. 9A is smaller than the area occupied by the light-receiving element 560 in the display device 10 illustrated in FIG. 8B. When the area occupied by the light-receiving element 560 is made small, the light-receiving range of each light-receiving element 560 can be narrowed. It is thus possible to reduce overlap between the light-receiving ranges of different light-receiving elements 560, e.g., adjacent light-receiving elements 560. This can inhibit blurring in an image captured using the light-receiving element 560 and failure in clear image capturing. Accordingly, for example, in the case where the display device 10 has a function of performing authentication such as fingerprint authentication, the area occupied by the light-receiving element 560 is preferably reduced because a clear fingerprint image can be captured, for example, which leads to higher authentication accuracy.

FIG. 9B is a cross-sectional view illustrating changes in the light-receiving range of the light-receiving element 560 when the area occupied by the light-receiving element 560, specifically, the length of the light-receiving element 560 in the X direction is changed. FIG. 9B illustrates the light-receiving element 560 on the bottom surface side of a layer 71 and a light-blocking layer 73 on the top surface side of the layer 71. FIG. 9B also illustrates the substrate 59 over the layer 71. In addition, a light-receiving element whose length in the X direction is made approximately three times as large as that of the light-receiving element 560 is referred to as a light-receiving element 560L.

In FIG. 9B, light that is incident on the light-receiving elements 560 is referred to as light 75 and is indicated by solid lines. In addition, light that is not incident on the light-receiving elements 560 but is incident on the light-receiving elements 560L is referred to as light 77 and is indicated by broken lines. Furthermore, the light-receiving range of each light-receiving element 560 is referred to as a light-receiving range 80, and the light-receiving range of each light-receiving element 560L is referred to as a light-receiving range 81.

As illustrated in FIG. 9B, the light-receiving range 80 of the light-receiving element 560 is narrower than the light-receiving range 81 of the light-receiving element 560L. That is, when the area occupied by the light-receiving element is made small, the light-receiving range of each light-receiving element is narrowed, which reduces overlap of the light-receiving ranges between different light-receiving elements. FIG. 9B illustrates an example where the light-receiving ranges 80 between adjacent light-receiving elements 560 are not overlapped with each other on a surface of the substrate 59 but some of the light-receiving ranges 81 between adjacent light-receiving elements 560L are partly overlapped with each other.

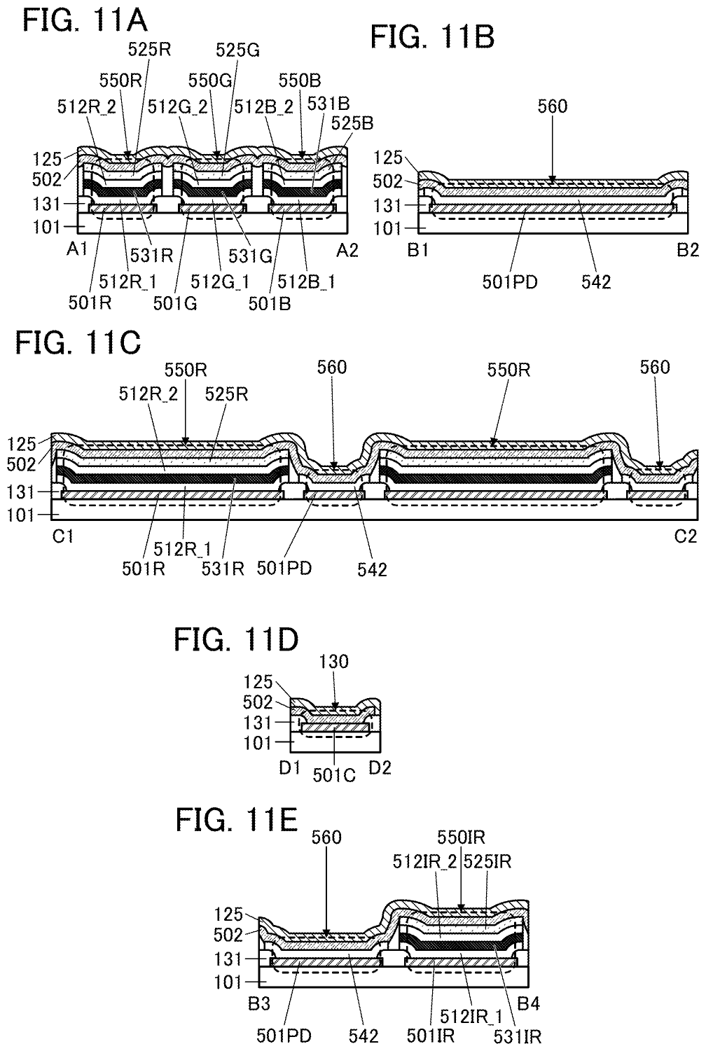

FIG. 10 is a schematic top view illustrating a structure example of the display device 10 and is a modification example of the display device 10 illustrated in FIG. 7A. The display device 10 illustrated in FIG. 10 differs from the display device 10 illustrated in FIG. 7A in that only part of the pixels 20 is provided with the light-receiving element 560.

When the display device 10 has the structure illustrated in FIG. 10, the drive frequency of the display device 10 can be increased. Thus, for example, in the case where the display device 10 has a function of a touch sensor or a near touch sensor, the position of an object that is in contact with or approaches the display device 10 can be detected quickly. Accordingly, for example, the movement of the object that is in contact with or approaches the display device 10 can be detected at high speed and with high accuracy.

### <Cross-Sectional Structure Example of Display Device>

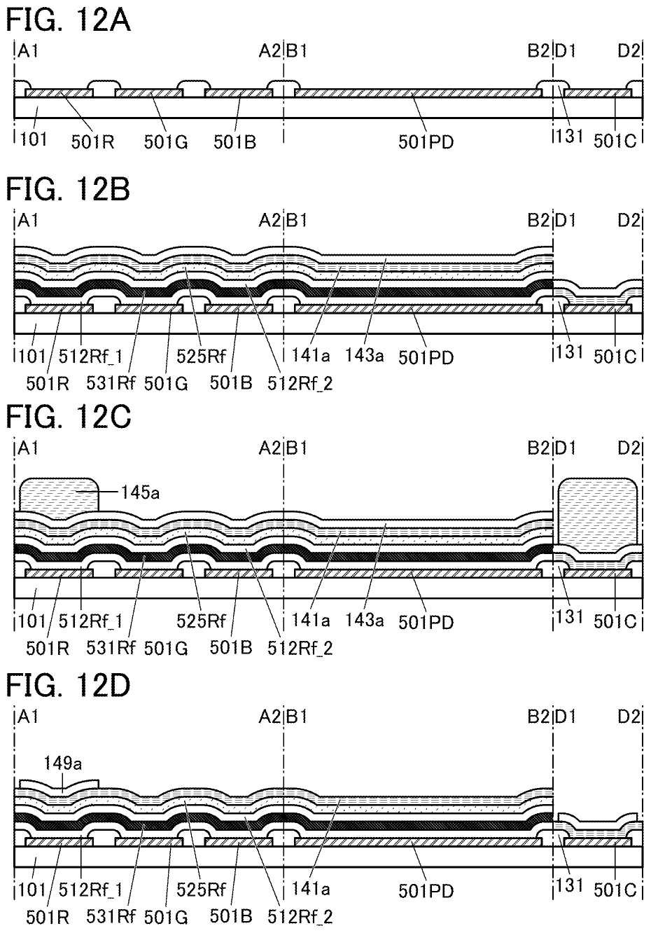

FIG. 11A is a cross-sectional view taken along dashed-dotted line A1-A2 in FIG. 7A, and FIG. 11B is a cross-sectional view taken along dashed-dotted line B1-B2 in FIG. 7A. In addition, FIG. 11C is a cross-sectional view taken along dashed-dotted line C1-C2 in FIG. 7A, and FIG. 11D is a cross-sectional view taken along dashed-dotted line D1-D2 in FIG. 7A. Furthermore, FIG. 11E is a cross-sectional view taken along dashed-dotted line B3-B4 in FIG. 8A. FIG. 11A to FIG. 11E each illustrate a structure example that corresponds to FIG. 2A.

The light-emitting element 550R, the light-emitting element 550G, the light-emitting element 550B, and the light-receiving element 560 are provided over a substrate 101. In addition, in the case where the display device 10 includes the light-emitting element 5501R, the light-emitting element 550IR is provided over the substrate 101.

In the case where the expression “B over A” or “B under A” is used in this specification and the like, for example, A and B do not always need to include a region where they are in contact with each other.

FIG. 11A illustrates a cross-sectional structure example of the light-emitting element 550R, the light-emitting element 550G, and the light-emitting element 550B. In addition, FIG. 11B illustrates a cross-sectional structure example of the light-receiving element 560.

As described above, the light-emitting element 550R includes the electrode 501R, the light-emitting unit 512R_1, the intermediate layer 531R, the light-emitting unit 512R_2, the layer 525R, and the electrode 502. The light-emitting element 550G includes the electrode 501G, the light-emitting unit 512G_1, the intermediate layer 531G, the light-emitting unit 512G_2, a layer 525G, and the electrode 502. The light-emitting element 550B includes the electrode 501B, the light-emitting unit 512B_1, the intermediate layer 531B, the light-emitting unit 512B_2, a layer 525B, and the electrode 502. The light-receiving element 560 includes the electrode 501PD, the light-receiving unit 542, and the electrode 502.

A gap is provided between the electrode 502 and an insulating layer 131. Accordingly, it is possible to inhibit the electrode 502 from being in contact with the side surface of the light-emitting unit 512 and the side surface of the light-receiving unit 542. Thus, short-circuit in the light-emitting element 550 and short-circuit in the light-receiving element 560 can be inhibited.

The shorter the distance between the light-emitting units 512 is, the more easily the gap is formed, for example. For example, when the distance between the light-emitting units 512 is less than or equal to 1 μm, preferably less than or equal to 500 nm, further preferably less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm, the gap can be suitably formed.

The insulating layer 131 is provided to cover end portions of the electrode 501R, end portions of the electrode 501G, end portions of the electrode 501B, and end portions of the electrode 501PD. End portions of the insulating layer 131 preferably have a tapered shape. Note that the insulating layer 131 is not necessarily provided when not needed.

For example, the light-emitting unit 512R_1, the light-emitting unit 512G_1, the light-emitting unit 512B_1, and the light-receiving unit 542 each include a region that is in contact with a top surface of the electrode 501 and a region that is in contact with a surface of the insulating layer 131. In addition, end portions of the light-emitting unit 512R_1, end portions of the light-emitting unit 512G_1, end portions of the light-emitting unit 512B_1, and end portions of the light-receiving unit 542 are positioned over the insulating layer 131.

As illustrated in FIG. 11A, a gap is provided between the light-emitting elements 550 that emit light of different colors, for example, between two light-emitting units 512. In this manner, for example, the light-emitting unit 512R_1, the light-emitting unit 512G_1, and the light-emitting unit 512B_1 are preferably provided not to be in contact with one another. In addition, for example, the light-emitting unit 512R_2, the light-emitting unit 512G_2, and the light-emitting unit 512B_2 are preferably provided not to be in contact with one another. This suitably prevents unintentional light emission due to current flowing through two adjacent light-emitting units 512. Thus, the contrast of the display device 10 can be increased, so that the display quality of the display device 10 can be increased.

A protective layer 125 is provided over the electrode 502. The protective layer 125 has a function of preventing diffusion of impurities such as water into the light-emitting element 550 and the light-receiving element 560 from above.

The protective layer 125 can have, for example, a single-layer structure or a stacked-layer structure at least including an inorganic insulating film. As the inorganic insulating film, for example, an oxide film and a nitride film, such as a silicon oxide film, a silicon oxynitride film, a silicon nitride oxide film, a silicon nitride film, an aluminum oxide film, an aluminum oxynitride film, and a hafnium oxide film can be given. Alternatively, a semiconductor material such as indium gallium oxide or indium gallium zinc oxide may be used for the protective layer 125.

In this specification and the like, a silicon oxynitride film refers to a film in which oxygen content is higher than nitrogen content in its composition. In addition, a silicon nitride oxide film refers to a film in which nitrogen content is higher than oxygen content in its composition.

Alternatively, a stacked-layer film of an inorganic insulating film and an organic insulating film can be used for the protective layer 125. For example, a structure in which an organic insulating film is sandwiched between a pair of inorganic insulating films is preferable. Furthermore, the organic insulating film preferably functions as a planarization film. This enables a top surface of the organic insulating film to be flat, and accordingly, coverage with the inorganic insulating film thereover is improved, which leads to an improvement in barrier properties. Moreover, a top surface of the protective layer 125 is flat, which is preferable because the influence of an uneven shape due to a lower structure can be reduced in the case where a component (e.g., a color filter, an electrode of a touch sensor, a lens array, or the like) is provided above the protective layer 125.

FIG. 11C illustrates a cross-sectional structure example of the display device 10 in the Y direction, specifically, a cross-sectional structure example of the light-emitting element 550R and the light-receiving element 560. Note that the light-emitting element 550G and the light-emitting element 550B can be arranged in the Y direction like the light-emitting element 550R.

FIG. 11D illustrates a connection portion 130 where the connection electrode 501C and the electrode 502 are electrically connected to each other. In the connection portion 130, the electrode 502 is provided on and in contact with the connection electrode 501C and the protective layer 125 is provided to cover the electrode 502. In addition, the insulating layer 131 is provided to cover end portions of the connection electrode 501C.

FIG. 11E illustrates a cross-sectional structure example of the light-emitting element 550IR in addition to the cross-sectional structure example of the light-receiving element 560. The light-emitting element 550IR includes an electrode 501IR, a light-emitting unit 512IR_1, an intermediate layer 531IR, a light-emitting unit 512IR_2, a layer 525IR, and the electrode 502.

The light-emitting unit 512IR_1 and the light-emitting unit 512IR_2 that are included in the light-emitting element 550IR include at least a light-emitting organic compound that emits light having intensity in an infrared light wavelength range. For example, the light-emitting unit 512IR_1 and the light-emitting unit 512IR_2 include a light-emitting organic compound that emits light having intensity in a near infrared light wavelength range. In the case where the display device 10 includes the light-emitting element 550IR, the light-receiving unit 542 included in the light-receiving element 560 includes, for example, an organic compound that has detection accuracy in an infrared light (e.g., near infrared light) wavelength range.

### <Example of Method for Manufacturing Display Device>

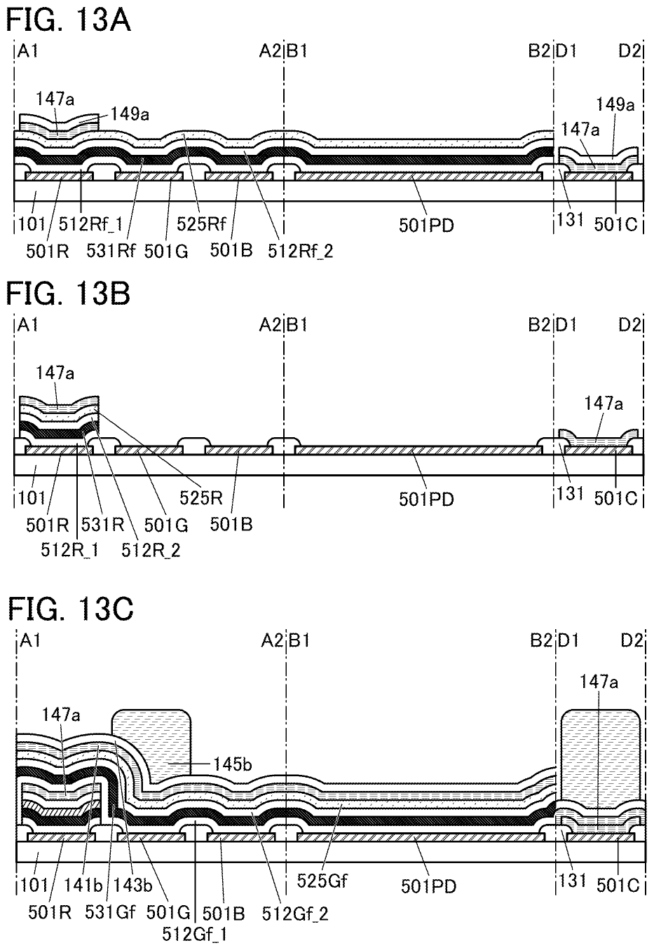

An example of a method for manufacturing the display device according to one embodiment of the present invention will be described below with reference to drawings. Here, a method for manufacturing the display device 10 illustrated in FIG. 7A and FIG. 11A to FIG. 11D is described as an example. FIG. 12A to FIG. 15C are schematic cross-sectional views in steps of the method for manufacturing the display device illustrated below. FIG. 12A to FIG. 15C illustrate cross sections corresponding to dashed-dotted line A1-A2, cross sections corresponding to dashed-dotted line B1-B2, and cross sections corresponding to dashed-dotted line D1-D2 in FIG. 7A.

Note that thin films included in the display device (insulating films, semiconductor films, conductive films, and the like) can be formed by a sputtering method, a CVD method, a vacuum evaporation method, a pulsed laser deposition (PLD) method, an ALD method, or the like. Examples of the CVD method include a plasma-enhanced chemical vapor deposition (PECVD) method, a thermal CVD method, and the like. In addition, an example of a thermal CVD method is a metal organic CVD (MOCVD) method.

Alternatively, thin films included in the display device (insulating films, semiconductor films, conductive films, and the like) can be formed by a method such as spin coating, dipping, spray coating, ink-jetting, dispensing, screen printing, offset printing, a doctor knife method, slit coating, roll coating, curtain coating, or knife coating.

In addition, when the thin films included in the display device are processed, a photolithography method can be used, for example. Besides, the thin films may be processed by a nanoimprinting method, a sandblasting method, a lift-off method, or the like.

There are the following two typical examples of a photolithography method. In one of the methods, a resist mask is formed over a thin film that is to be processed, the thin film is processed by etching, and the resist mask is removed. In the other method, a photosensitive thin film is deposited and then processed into a desired shape by exposure and development.

For light used for exposure in a photolithography method, for example, an i-line (with a wavelength of 365 nm), a g-line (with a wavelength of 436 nm), an h-line (with a wavelength of 405 nm), or light in which these lines are mixed can be used. Besides, ultraviolet light, KrF laser light, ArF laser light, or the like can be used. In addition, exposure may be performed by liquid immersion exposure technique. Alternatively, for the light used for the exposure, extreme ultraviolet (EUV) light, X-rays, or the like may be used. Furthermore, instead of the light used for the exposure, an electron beam can also be used. It is preferable to use extreme ultraviolet light, X-rays, or an electron beam because extremely minute processing is possible. Note that when exposure is performed by scanning of a beam such as an electron beam, a photomask is unnecessary.

For etching of the thin films, a dry etching method, a wet etching method, a sandblasting method, or the like can be used.

In order to manufacture the display device 10, the substrate 101 is prepared first. As the substrate 101, a substrate having at least heat resistance high enough to withstand the following heat treatment can be used. In the case where an insulating substrate is used as the substrate 101, a glass substrate, a quartz substrate, a sapphire substrate, a ceramic substrate, an organic resin substrate, or the like can be given. Alternatively, it is possible to use a semiconductor substrate such as a single crystal semiconductor substrate or a polycrystalline semiconductor substrate including silicon, silicon carbide, or the like as a material; a compound semiconductor substrate of silicon germanium or the like; or an SOI substrate.

Then, the electrode 501R, the electrode 501G, the electrode 501B, the electrode 501PD, and the connection electrode 501C are formed over the substrate 101. First, a conductive film is deposited, a resist mask is formed by a photolithography method, and an unnecessary portion of the conductive film is removed by etching. After that, the resist mask is removed, so that the electrode 501R, the electrode 501G, and the electrode 501B can be formed.

In the case where a conductive film that has a property of reflecting visible light is used as the conductive film, it is preferable to employ a material having reflectance as high as possible in the entire wavelength range of visible light (e.g., silver, aluminum, or the like). This can increase color reproducibility as well as light extraction efficiency of the light-emitting elements.

Then, the insulating layer 131 is formed to cover the end portions of the electrode 501R, the electrode 501G, the electrode 501B, and the electrode 501PD (FIG. 12A). An organic insulating film or an inorganic insulating film can be used for the insulating layer 131. The end portions of the insulating layer 131 preferably have a tapered shape to improve step coverage with a film in a later step. In particular, when an organic insulating film is used, a photosensitive material is preferably used so that the shape of the end portions can be easily controlled by exposure and development conditions. Note that for the insulating layer 131, an inorganic insulating film may be used. Using an inorganic insulating film for the insulating layer 131 enables the display device 10 to have high resolution.

Then, a layer 512Rf_1 to be the light-emitting unit 512R_1 in a later step is formed over the electrode 501R, the electrode 501G, the electrode 501B, the electrode 501PD, and the insulating layer 131. Specifically, a film to be the layer 521, a film to be the layer 522, a light-emitting film to be the light-emitting layer 523R, and a film to be the layer 524 in a later step are sequentially deposited. After that, an intermediate film 531Rf to be the intermediate layer 531R in a later step is deposited over the layer 512Rf_1.

Then, a layer 512Rf_2 to be the light-emitting unit 512R_2 in a later step is formed over the intermediate film 531Rf. Specifically, the film to be the layer 522, the light-emitting film to be the light-emitting layer 523R, and the film to be the layer 524 in a later step are sequentially deposited. After that, a film 525Rf to be the layer 525R in a later step is deposited over the layer 512Rf_2.

A film included in the layer 512Rf_1, the intermediate film 531Rf, a film included in the layer 512Rf_2, and the film 525Rf can be formed by, for example, an evaporation method, a sputtering method, an inkjet method, or the like. Note that without limitation to this, the above deposition method can be used as appropriate.

The layer 512Rf_1, the intermediate film 531Rf, the layer 512Rf_2, and the film 525Rf are preferably formed not to be provided over the connection electrode 501C. For example, in the case where the film included in the layer 512Rf_1, the intermediate film 531Rf, the film included in the layer 512Rf_2, and the film 525Rf are formed by an evaporation method or a sputtering method, these films are preferably formed using a shielding mask so that the film included in the layer 512Rf_1, the intermediate film 531Rf, the film included in the layer 512Rf_2, and the film 525Rf are not deposited over the connection electrode 501C.

Then, a sacrificial film 141a is deposited over the film 525Rf. Alternatively, the sacrificial film 141a can be provided in contact with the top surface of the connection electrode 501C.

As the sacrificial film 141a, it is possible to use a film that has high tolerance to etching processing of the film 525Rf, the film included in the layer 512Rf_2, the intermediate film 531Rf, and the film included in the layer 512Rf_1, that is, a film having high etching selectivity. Alternatively, as the sacrificial film 141a, it is possible to use a film having high etching selectivity with respect to a protective film such as a protective film 143a described later. Alternatively, as the sacrificial film 141a, it is possible to use a film that can be removed by a wet etching method with which damage to the film 525Rf, the film included in the layer 512Rf_2 the intermediate film 531Rf, and the film included in the layer 512Rf_1 is small.

An inorganic film such as a metal film, an alloy film, a metal oxide film, a semiconductor film, or an inorganic insulating film can be used as the sacrificial film 141a, for example. The sacrificial film 141a can be formed by a variety of deposition methods such as a sputtering method, an evaporation method, a CVD method, and an ALD method.

For the sacrificial film 141a, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used, for example. It is particularly preferable to use a low-melting-point material such as aluminum or silver.

Alternatively, for the sacrificial film 141a, a metal oxide such as an indium gallium zinc oxide (an In—Ga—Zn oxide, also referred to as IGZO) can be used. It is also possible to use indium oxide, an indium zinc oxide (an In—Zn oxide), an indium tin oxide (an In—Sn oxide), an indium titanium oxide (an In—Ti oxide), an indium tin zinc oxide (an In—Sn—Zn oxide), an indium titanium zinc oxide (an In—Ti—Zn oxide), an indium gallium tin zinc oxide (an In—Ga—Sn—Zn oxide), or the like. Alternatively, an indium tin oxide containing silicon can also be used.

Note that an element M (M is one or more kinds selected from aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) can be employed instead of gallium.

Alternatively, an inorganic insulating material such as aluminum oxide, hafnium oxide, or silicon oxide can be used for the sacrificial film 141a.

Alternatively, for the sacrificial film 141a, it is preferable to use a material that can be dissolved in a solvent chemically stable with respect to at least the film 525Rf. In particular, a material that is dissolved in water or alcohol can be suitably used for the sacrificial film 141a. In deposition of the sacrificial film 141a, it is preferable that application of such a material that has been dissolved in a solvent such as water or alcohol be performed by a wet deposition method and followed by heat treatment for evaporating the solvent. At this time, the heat treatment is preferably performed in a reduced-pressure atmosphere because the solvent can be removed at a low temperature in a short time and thermal damage to the film 525Rf, the layer 512Rf_2, the intermediate film 531Rf, and the layer 512Rf_1 can be reduced accordingly.

Examples of the wet deposition method that can be used for forming the sacrificial film 141a include spin coating, dipping, spray coating, ink-jetting, dispensing, screen printing, offset printing, a doctor knife method, slit coating, roll coating, curtain coating, knife coating, and the like.

For the sacrificial film 141a, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin can be used.

Next, the protective film 143a is formed over the sacrificial film 141a (FIG. 12B).

The protective film 143a is a film used as a hard mask when the sacrificial film 141a is etched later. In addition, when the sacrificial film 143a is etched later, the sacrificial film 141a is exposed. Thus, a combination of films having high etching selectivity therebetween is selected for the sacrificial film 141a and the protective film 143a. It is thus possible to select a film that can be used for the protective film 143a depending on an etching condition of the sacrificial film 141a and an etching condition of the protective film 143a.

For example, in the case where dry etching using a gas containing fluorine (also referred to as a fluorine-based gas) is used for etching of the protective film 143a, silicon, silicon nitride, silicon oxide, tungsten, titanium, molybdenum, tantalum, tantalum nitride, an alloy containing molybdenum and niobium, an alloy containing molybdenum and tungsten, or the like can be used for the protective film 143a. Here, for example, a metal oxide film such as IGZO or ITO is given as a film having high etching selectivity (that is, enabling low etching rate) in dry etching using the fluorine-based gas, and such a film can be used as the sacrificial film 141a.

Note that without being limited to this, a material of the protective film 143a can be selected from a variety of materials depending on the etching condition of the sacrificial film 141a and the etching condition of the protective film 143a. For example, the material of the protective film 143a can be selected from the films that can be used as the sacrificial film 141a.

Alternatively, a nitride film can be used as the protective film 143a, for example. Specifically, it is also possible to use a nitride such as silicon nitride, aluminum nitride, hafnium nitride, titanium nitride, tantalum nitride, tungsten nitride, gallium nitride, or germanium nitride.

Alternatively, an oxide film can be used as the protective film 143a. An oxide film or an oxynitride film of silicon oxide, silicon oxynitride, aluminum oxide, aluminum oxynitride, hafnium oxide, hafnium oxynitride, or the like can also be typically used.

Then, over the protective film 143a, a resist mask 145a is formed in each of a position overlapped with the electrode 501R and a position overlapped with the connection electrode 501C (FIG. 12C).

For the resist mask 145a, a resist material containing a photosensitive resin, such as a positive type resist material or a negative type resist material can be used.

Here, in the case where the protective film 143a is not formed and the resist mask 145a is formed over the sacrificial film 141a, when a defect such as a pinhole exists in the sacrificial film 141a, there is a risk of dissolving the film 525Rf, for example, due to a solvent of the resist material. Such a defect can be prevented by using the protective film 143a.

Note that in the case where a film that is unlikely to cause a defect such as a pinhole is used as the sacrificial film 141a, the resist mask 145a may be formed directly on the sacrificial film 141a without using the protective film 143a.

Next, part of the protective film 143a that is not covered with the resist mask 145a is removed by etching, so that a protective layer 149a is formed. At this time, the protective layer 149a is concurrently formed also over the connection electrode 501C.

In the etching of the protective film 143a, an etching condition with high selectively is preferably used so that the sacrificial film 141a is not removed by the etching. Either wet etching or dry etching can be performed for the etching of the protective film 143a. With the use of dry etching, a reduction in a processing pattern of the protective film 143a can be inhibited.

Next, the resist masks 145a are removed (FIG. 12D).

The resist masks 145a can be removed by wet etching or dry etching. It is particularly preferable to perform dry etching (also referred to as plasma ashing) using an oxygen gas as an etching gas to remove the resist masks 145a.

At this time, the resist masks 145a are removed in a state where the sacrificial film 141a is provided over the film 525Rf; thus, the influence on the film 525Rf, the layer 512Rf_2, the intermediate film 531Rf, and the layer 512Rf_1 is inhibited. In particular, when the layer 512Rf_1 and the layer 512Rf_2 are exposed to oxygen, electrical characteristics are adversely affected in some cases; therefore, removal of the resist masks 145a in the state where the sacrificial film 141a is provided over the film 525Rf is suitable when etching using an oxygen gas, such as plasma ashing, is performed.

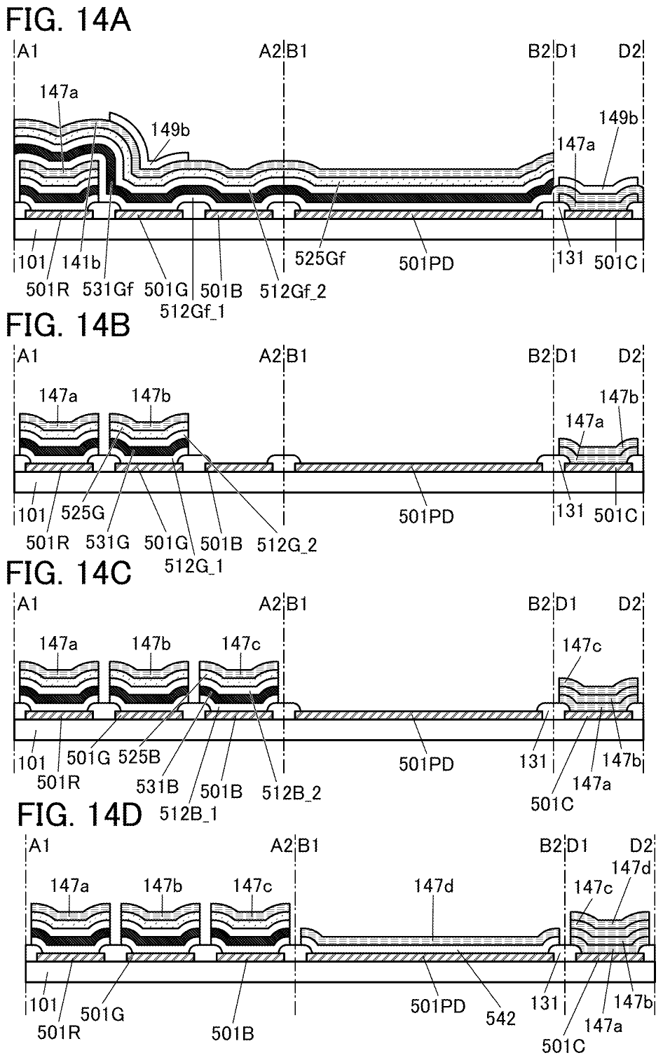

Next, part of the sacrificial film 141a that is not covered with the protective layer 149a is removed by etching with the use of the protective layer 149a as a mask, so that a sacrificial layer 147a is formed (FIG. 13A). At this time, the sacrificial layer 147a is concurrently formed also over the connection electrode 501C.

Either wet etching or dry etching can be performed for the etching of the sacrificial film 141a. The use of a dry etching method is preferable because pattern shrinkage can be inhibited.

Then, the protective layer 149a is removed by etching and parts of the film 525Rf, the layer 512Rf_2, the intermediate film 531Rf, and the layer 512Rf_1 that are not covered with the sacrificial layer 147a are removed by etching, so that the layer 525R, the light-emitting unit 512R_2, the intermediate layer 531R, and the light-emitting unit 512R_1 are formed (FIG. 13B).

In particular, for etching of the film 525Rf, the layer 512Rf_2, the intermediate film 531Rf, and the layer 512Rf_1, it is preferable to use dry etching using an etching gas that does not contain oxygen as its main component. Accordingly, a change in the quality of the film 525Rf, the layer 512Rf_2, the intermediate film 531Rf, and the layer 512Rf_1 can be inhibited, which leads to a highly reliable display device. Examples of the etching gas that does not contain oxygen as its main component include CF₄, C₄F₆, SF₆, CHF₃, Cl₂, H₂O, BCl₃, H₂, and a noble gas. Helium can be used as the noble gas, for example. Alternatively, a mixed gas of the above gas and a dilution gas that does not contain oxygen can be used as the etching gas.

Then, a layer 512Gf_1 to be the light-emitting unit 512G_1 in a later step, an intermediate film 531Gf to be the intermediate layer 531G in a later step, a layer 512Gf_2 to be the light-emitting unit 512G_2 in a later step, and a film 525Gf to be the layer 525G in a later step are sequentially deposited over the sacrificial layer 147a, the insulating layer 131, the electrode 501G, the electrode 501B, and the electrode 501PD. At this time, it is preferable not to provide the layer 512Gf_1, the intermediate film 531Gf, the layer 512Gf_2, and the film 525Gf over the connection electrode 501C.

For a deposition method and the like of a film included in the layer 512Gf_1, the intermediate film 531Gf, a film included in the layer 512Gf_2, and the film 525Gf, the description of the deposition method and the like of the film included in the layer 512Rf_1, the intermediate film 531Rf, the film included in the layer 512Rf_2, and the film 525Rf can be referred to.

Then, a sacrificial film 141b is formed over the film 525Gf. The sacrificial film 141b can be formed in a manner similar to that for the sacrificial film 141a. In particular, for the sacrificial film 141b, it is preferable to use the same material as that for the sacrificial film 141a.

At this time, the sacrificial film 141b is concurrently deposited also over the connection electrode 501C to cover the sacrificial layer 147a.

Next, a protective film 143b is formed over the sacrificial film 141b. The protective film 143b can be formed in a manner similar to that for the protective film 143a. In particular, for the protective film 143b, it is preferable to use the same material as that for the protective film 143a.

Then, over the protective film 143b, a resist mask 145b is formed in each of a position overlapped with the electrode 501G and a position overlapped with the connection electrode 501C (FIG. 13C).

The resist mask 145b can be formed in a manner similar to that for the resist mask 145a.

Next, part of the protective film 143b that is not covered with the resist mask 145b is removed by etching, so that a protective layer 149b is formed. At this time, the protective layer 149b is concurrently formed also over the connection electrode 501C.

For etching of the protective film 143b, the description of the protective film 143a can be referred to.

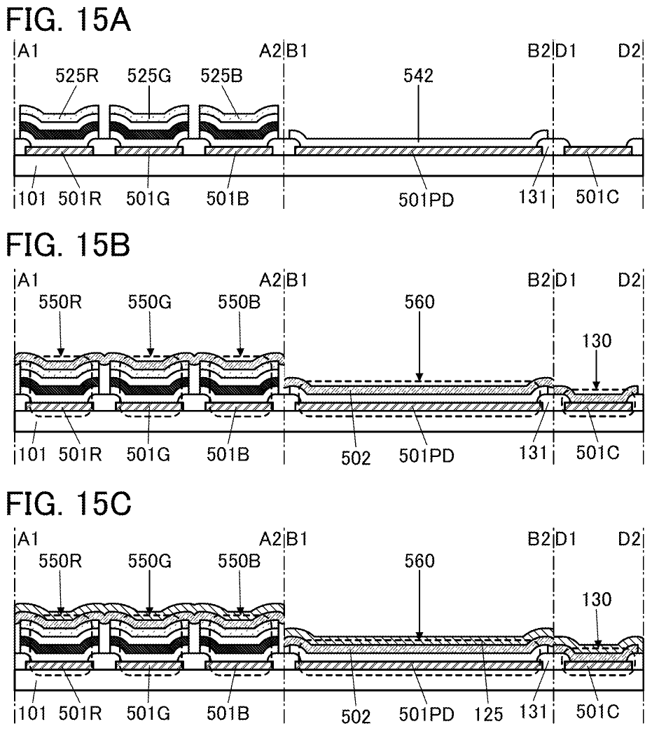

Next, the resist masks 145b are removed (FIG. 14A). For removal of the resist masks 145b, the description of the resist masks 145a can be referred to.

Next, part of the sacrificial film 141b that is not covered with the protective layer 149b is removed by etching with the use of the protective layer 149b as a mask, so that a sacrificial layer 147b is formed. At this time, the sacrificial layer 147b is concurrently formed also over the connection electrode 501C. The sacrificial layer 147a and the sacrificial layer 147b are stacked over the connection electrode 501C.

For etching of the sacrificial film 141b, the description of the sacrificial film 141a can be referred to.

Then, the protective layer 149b is removed by etching and parts of the film 525Gf, the layer 512Gf_2, the intermediate film 531Gf, and the layer 512Gf_1 that are not covered with the sacrificial layer 147b are removed by etching, so that the layer 525G, the light-emitting unit 512G_2, the intermediate layer 531G, and the light-emitting unit 512G_1 are formed (FIG. 14B).

For etching of the film 525Gf, the layer 512Gf_2, the intermediate film 531Gf, the layer 512Gf_1, and the protective layer 149b, the description of the film 525Rf, the layer 512Rf_2, the intermediate film 531Rf, the layer 512Rf_1, and the protective layer 149a can be referred to.

At this time, since the layer 525R, the light-emitting unit 512R_2, the intermediate layer 531R, and the light-emitting unit 512R_1 are protected by the sacrificial layer 147a, it is possible to prevent damage caused by a step of etching the film 525Gf, the layer 512Gf_2, the intermediate film 531Gf, and the layer 512Gf_1.

In this manner, the light-emitting unit 512R_1, the intermediate layer 531R, the light-emitting unit 512R_2, and the layer 525R can be formed separately from the light-emitting unit 512G_1, the intermediate layer 531G, the light-emitting unit 512G_2, and the layer 525G with high positional accuracy.

The light-emitting unit 512B_1, the intermediate layer 531i, the light-emitting unit 512B_2, the layer 525B, and a sacrificial layer 147c can be formed through a step similar to the above step (FIG. 14C). The sacrificial layer 147a, the sacrificial layer 147b, and the sacrificial layer 147c are stacked over the connection electrode 501C.

After the light-emitting unit 512B_1, the intermediate layer 531i, the light-emitting unit 512B_2, the layer 525B, and the sacrificial layer 147c are formed, the light-receiving unit 542 and a sacrificial layer 147d are formed through a step similar to the above step (FIG. 14D). The sacrificial layer 147a, the sacrificial layer 147b, the sacrificial layer 147c, and the sacrificial layer 147d are stacked over the connection electrode 501C.

In addition, in the case where a display device that includes the light-emitting element 550IR is manufactured, for example, after the light-emitting unit 512B_1, the intermediate layer 531i, the light-emitting unit 512B_2, the layer 525B, and the sacrificial layer 147c are formed and before the light-receiving unit 542 and the sacrificial layer 147d are formed, the light-emitting unit 512IR_1, the intermediate layer 531IR, the light-emitting unit 512IR_2, the layer 525IR, and a sacrificial layer are formed through a step similar to the above step. In that case, five sacrificial layers are stacked over the connection electrode 501C.

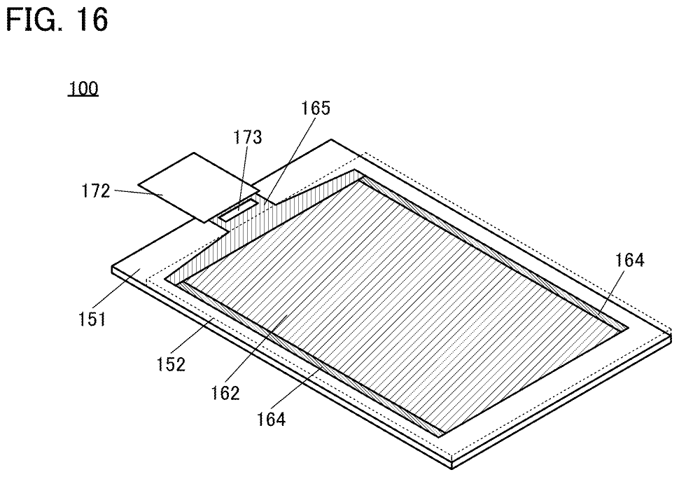

Then, the sacrificial layer 147a, the sacrificial layer 147b, the sacrificial layer 147c, and the sacrificial layer 147d are removed, so that a top surface of the layer 525R, a top surface of the layer 525G, a top surface of the layer 525B, and a top surface of the light-receiving unit 542 are exposed (FIG. 15A). At this time, the top surface of the connection electrode 501C is concurrently also exposed.

The sacrificial layer 147a, the sacrificial layer 147b, the sacrificial layer 147c, and the sacrificial layer 147d can be removed by wet etching or dry etching. At this time, it is preferable to use a method that causes damage to the light-emitting unit 512, the intermediate layer 531, the layer 525, and the light-receiving unit 542 as little as possible. In particular, a wet etching method is preferably used. For example, it is preferable to use wet etching using a tetramethyl ammonium hydroxide (TMAH) aqueous solution, diluted hydrofluoric acid, oxalic acid, phosphoric acid, acetic acid, nitric acid, or a mixed solution thereof.

Alternatively, the sacrificial layer 147a, the sacrificial layer 147b, the sacrificial layer 147c, and the sacrificial layer 147d are preferably removed by being dissolved in a solvent such as water or alcohol. Here, as alcohol in which the sacrificial layer 147a, the sacrificial layer 147b, the sacrificial layer 147c, and the sacrificial layer 147d can be dissolved, a variety of alcohols such as ethyl alcohol, methyl alcohol, isopropyl alcohol (IPA), and glycerin can be used.

After the sacrificial layer 147a, the sacrificial layer 147b, the sacrificial layer 147c, and the sacrificial layer 147d are removed, drying treatment is preferably performed in order to remove water contained in the light-emitting unit 512, the light-receiving unit 542, and the like and water adsorbed on surfaces of the light-emitting unit 512, the light-receiving unit 542, and the like. For example, heat treatment is preferably performed in an inert gas atmosphere or a reduced-pressure atmosphere. The heat treatment can be performed at a substrate temperature of higher than or equal to 50° C. and lower than or equal to 200° C., preferably higher than or equal to 60° C. and lower than or equal to 150° C., further preferably higher than or equal to 70° C. and lower than or equal to 120° C. The heat treatment is preferably performed in a reduced-pressure atmosphere because drying at a lower temperature is possible.

In this manner, the light-emitting unit 512R, the light-emitting unit 512G, the light-emitting unit 512B, the light-receiving unit 542, and the like can be separately formed.

Then, the electrode 502 is formed over the layer 525R, the layer 525G, the layer 525B, the light-receiving unit 542, and the connection electrode 501C (FIG. 15B). As described above, a gap can be formed between the electrode 502 and the insulating layer 131.

The electrode 502 can be formed by a deposition method such as an evaporation method or a sputtering method. Alternatively, a film formed by an evaporation method and a film formed by a sputtering method may be stacked. The electrode 502 is preferably formed using a shielding mask.

The electrode 502 is electrically connected to the connection electrode 501C outside a display portion.

Then, the protective layer 125 is formed over the electrode 502 (FIG. 15C). An inorganic insulating film used for the protective layer 125 is preferably deposited by a sputtering method, a PECVD method, or an ALD method. In particular, an ALD method is preferable because it provides excellent step coverage and is less likely to cause a defect such as a pinhole.

In addition, an organic insulating film is preferably formed by an inkjet method because a uniform film can be formed in a desired area.

In the above manner, the display device 10 can be manufactured.

As described above, in the method for manufacturing the display device according to one embodiment of the present invention, the light-emitting elements 550 can be formed separately without using a shadow mask such as a metal mask. This enables further miniaturization of subpixels compared to the case of separately forming the light-emitting elements 550 by using a shadow mask and an increase in pixel aperture ratio. Moreover, since the light-emitting units 512 can be formed separately, it is possible to achieve a display device that performs extremely clear display with high contrast and high display quality.

Miniaturization of subpixels enables providing subpixels that do not contribute to display in a pixel. For example, a subpixel including the light-receiving element 560 can be provided in a pixel, and a subpixel including the light-emitting element 550IR that emits infrared light can be provided in the pixel. Even in the case where subpixels that do not contribute to display are provided in a pixel, the display device according to one embodiment of the present invention can inhibit a decrease in pixel density. For example, the pixel density can be higher than or equal to 400 ppi, can be higher than or equal to 1000 ppi, can be higher than or equal to 3000 ppi, or can be higher than or equal to 5000 ppi.

At least part of the structure examples, the drawings corresponding thereto, and the like illustrated in this embodiment can be combined with the other structure examples, the other drawings, and the like as appropriate.

At least part of this embodiment can be implemented in combination with the other embodiments described in this specification as appropriate.

### Embodiment 2

In this embodiment, structure examples of a display device according to one embodiment of the present invention are described.

### Structure Example 1

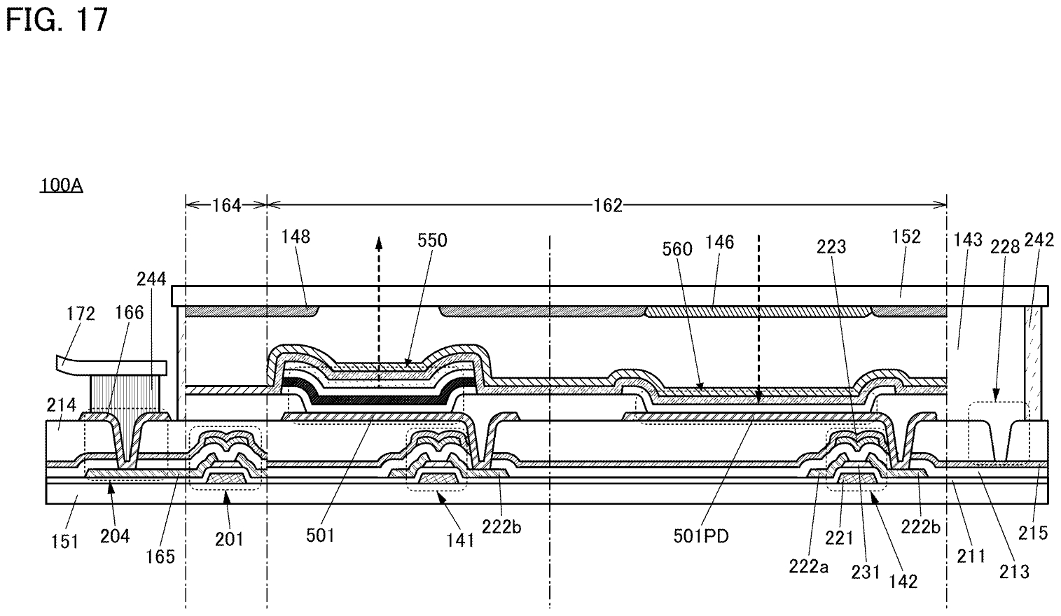

FIG. 16 is a perspective view illustrating a structure example of a display device 100. The display device 100 has a structure in which a substrate 151 and a substrate 152 are attached to each other. In FIG. 16, the substrate 152 is denoted by a dashed line.

The display device 100 includes a display portion 162, a circuit 164, a wiring 165, and the like. FIG. 16 also illustrates an example in which an IC (integrated circuit) 173 and an FPC 172 are mounted on the display device 100. Therefore, the structure illustrated in FIG. 16 can be regarded as a display module including the display device, the IC, and the FPC.

The circuit 164 can be a gate driver, for example. A signal and power can be supplied to the circuit 164 through the wiring 165, for example. The signal and power can be input to the wiring 165 through the FPC 172 from the outside of the display device 10, for example. Alternatively, the IC 173 can generate the signal and power and can output the signal and power to the wiring 165.

Although FIG. 16 illustrates an example in which the IC 173 is provided on the substrate 151 by a COG (Chip On Glass) method, a TCP (Tape Carrier Package) method, a COF (Chip On Film) method, or the like may be used.

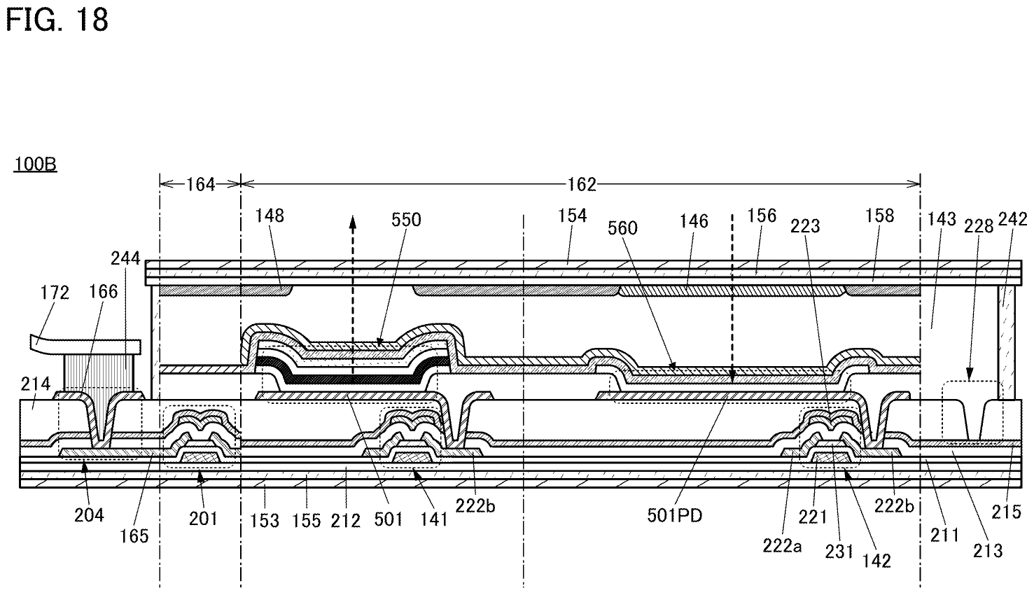

FIG. 17 is a diagram illustrating an example of cross sections of part of a region including the FPC 172, part of a region including the circuit 164, part of a region including the display portion 162, and part of a region including an end portion in the display device 100 illustrated in FIG. 16. Note that the display device 100 illustrated in FIG. 17 is a display device 100A.

The display device 100A includes a transistor 201, a transistor 141, a transistor 142, the light-emitting element 550, the light-receiving element 560, and the like between the substrate 151 and the substrate 152.

The substrate 152 and an insulating layer 214 are bonded to each other with an adhesive layer 242. A solid sealing structure, a hollow sealing structure, or the like can be employed to seal the light-emitting element 550 and the light-receiving element 560. A hollow sealing structure is employed in which a space 143 surrounded by the substrate 152, the adhesive layer 242, and the insulating layer 214 is filled with an inert gas (nitrogen, argon, or the like). The adhesive layer 242 may be provided to be overlapped with the light-emitting element 550. In addition, a region surrounded by the substrate 152, the adhesive layer 242, and the insulating layer 214 may be filled with a resin different from that of the adhesive layer 242.

The electrode 501 included in the light-emitting element 550 is electrically connected to a conductive layer 222b included in the transistor 141 through an opening provided in the insulating layer 214. The transistor 142 has a function of controlling driving of the light-emitting element 550. The electrode 501PD included in the light-receiving element 560 is electrically connected to the conductive layer 222b included in the transistor 142 through an opening provided in the insulating layer 214.

Light from the light-emitting element 550 is emitted toward the substrate 152 side. In addition, light enters the light-receiving element 560 through the substrate 152 and the space 143. For the substrate 152, a material having a high transmitting property with respect to visible light and infrared light is preferably used.

A light-blocking layer 148 is provided on a surface of the substrate 152 on the substrate 151 side. The light-blocking layer 148 has openings in a position overlapped with the light-receiving element 560 and in a position overlapped with the light-emitting element 550. In addition, a filter 146 that filters out ultraviolet light is provided in a position overlapped with the light-receiving element 560. Note that a structure without the filter 146 can be employed.

The transistor 201, the transistor 141, and the transistor 142 are all formed over the substrate 151. These transistors can be formed using the same material in the same step.

An insulating layer 211, an insulating layer 213, an insulating layer 215, and the insulating layer 214 are provided in this order over the substrate 151. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that there is no limitation on the number of gate insulating layers and the number of insulating layers covering the transistors, and each insulating layer may be either a single layer or two or more layers.

A material into which impurities such as water and hydrogen are less likely to diffuse is preferably used for at least one of the insulating layers that cover the transistors. This allows the insulating layer to serve as a barrier layer. Such a structure can effectively inhibit diffusion of impurities into the transistors from the outside and increase the reliability of the display device.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, or an aluminum nitride film can be used. Alternatively, a hafnium oxide film, an yttrium oxide film, a zirconium oxide film, a gallium oxide film, a tantalum oxide film, a magnesium oxide film, a lanthanum oxide film, a cerium oxide film, or a neodymium oxide film may be used. A stack including two or more of the above insulating films may also be used.

An organic insulating film is preferably used for the insulating layer 214 functioning as a planarization layer. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins.

Here, an organic insulating film often has a lower barrier property against impurities than an inorganic insulating film. Therefore, the organic insulating film preferably has an opening in the vicinity of an end portion of the display device 100A. This can inhibit diffusion of impurities from the end portion of the display device 100A through the organic insulating film. Alternatively, in order to prevent the organic insulating film from being exposed at the end portion of the display device 100A, the organic insulating film may be formed so that its end portion is positioned on the inner side compared to the end portion of the display device 100A.

In a region 228 illustrated in FIG. 17, an opening is formed in the insulating layer 214. This can inhibit diffusion of impurities into the display portion 162 from the outside through the insulating layer 214 even when an organic insulating film is used as the insulating layer 214. Thus, the reliability of the display device 100A can be increased.

The transistor 201, the transistor 141, and the transistor 142 each include a conductive layer 221 functioning as a gate, the insulating layer 211 functioning as the gate insulating layer, a conductive layer 222a and the conductive layer 222b functioning as a source and a drain, a semiconductor layer 231, the insulating layer 213 functioning as the gate insulating layer, and a conductive layer 223 functioning as a gate. Here, a plurality of layers obtained by processing the same conductive film are illustrated with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structures of the transistors included in the display device of this embodiment. For example, a planar transistor, a staggered transistor, an inverted staggered transistor, or the like can be used. In addition, the transistor structure may be either a top-gate structure or a bottom-gate structure. Alternatively, gates may be provided above and below a semiconductor layer where a channel is formed.

A structure in which the semiconductor layer where a channel is formed is sandwiched between the two gates is used for the transistor 201, the transistor 141, and the transistor 142. The two gates may be connected to each other and supplied with the same signal to drive the transistor. Alternatively, one of the two gates may be supplied with a potential for controlling the threshold voltage of the transistor and the other may be supplied with a potential for driving.

There is no particular limitation on the crystallinity of a semiconductor material used for the transistors, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used because degradation of the transistor characteristics can be inhibited.

A semiconductor layer of a transistor preferably contains a metal oxide (also referred to as an oxide semiconductor). Alternatively, the semiconductor layer of the transistor may contain silicon. Examples of silicon include amorphous silicon and crystalline silicon (low-temperature polysilicon, single crystal silicon, and the like).

When the semiconductor layer contains a metal oxide, the metal oxide preferably contains at least indium or zinc as described above. In particular, indium and zinc are preferably contained. In addition to them, aluminum, gallium, yttrium, tin, or the like is preferably contained. Furthermore, one or more kinds selected from boron, silicon, titanium, iron, nickel, germanium, zirconium, molybdenum, lanthanum, cerium, neodymium, hafnium, tantalum, tungsten, magnesium, cobalt, and the like may be contained.

The transistors included in the circuit 164 and the transistors included in the display portion 162 may have either the same structure or different structures. A plurality of transistors included in the circuit 164 may have either the same structure or two or more kinds of structures. Similarly, a plurality of transistors included in the display portion 162 may have either the same structure or two or more kinds of structures.

A connection portion 204 is provided in a region that is over the substrate 151 and does not overlap the substrate 152. In the connection portion 204, the wiring 165 is electrically connected to the FPC 172 through a conductive layer 166 and a connection layer 244. On a top surface of the connection portion 204, the conductive layer 166 obtained by processing the same conductive film as the electrode 501 is exposed. Thus, the connection portion 204 and the FPC 172 can be electrically connected to each other through the connection layer 244.

A variety of optical members can be arranged on an outer side of the substrate 152. Examples of the optical members include a polarizing plate, a retardation plate, a light diffusion layer (a diffusion film or the like), an anti-reflective layer, and a light-condensing film. Furthermore, an antistatic film inhibiting attachment of dust, a water repellent film suppressing attachment of stain, a hard coat film inhibiting generation of a scratch caused by the use, a shock absorbing layer, or the like may be provided on the outer side of the substrate 152.

Glass, quartz, ceramic, sapphire, a resin, or the like can be used for the substrate 151 and the substrate 152.

For the adhesive layer, a variety of curable adhesives, e.g., a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. Alternatively, a two-liquid-mixture-type resin may be used. Alternatively, an adhesive sheet may be used, for example.

As the connection layer 244, an anisotropic conductive film (ACF), an anisotropic conductive paste (ACP), or the like can be used.

As materials that can be used for conductive layers such as a variety of wirings and electrodes that constitute a display device, in addition to a gate, a source, and a drain of a transistor, metals such as aluminum, titanium, chromium, nickel, copper, yttrium, zirconium, molybdenum, silver, tantalum, or tungsten, an alloy containing the metal as its main component, and the like can be given. A film containing these materials can be used as a single-layer structure or a stacked-layer structure.

In addition, as a light-transmitting conductive material, a conductive oxide such as indium oxide, indium tin oxide, indium zinc oxide, zinc oxide, or zinc oxide containing gallium can be used or graphene can be used. Alternatively, a metal material such as gold, silver, platinum, magnesium, nickel, tungsten, chromium, molybdenum, iron, cobalt, copper, palladium, or titanium, or an alloy material containing the metal material can be used. Alternatively, a nitride of the metal material (e.g., titanium nitride) or the like may be used. Note that in the case of using the metal material or the alloy material (or the nitride thereof), the material is made thin enough to have a light-transmitting property. Furthermore, a stacked-layer film of the above materials can be used for a conductive layer. For example, a stacked-layer film of indium tin oxide and an alloy of silver and magnesium, or the like is preferably used for increased conductivity. They can also be used for conductive layers such as a variety of wirings and electrodes that constitute a display device, and conductive layers (conductive layers functioning as a pixel electrode or a common electrode) included in a display element.

As an insulating material that can be used for each insulating layer, for example, a resin such as an acrylic resin or an epoxy resin, and an inorganic insulating material such as silicon oxide, silicon oxynitride, silicon nitride oxide, silicon nitride, or aluminum oxide can be given.

### Structure Example 2

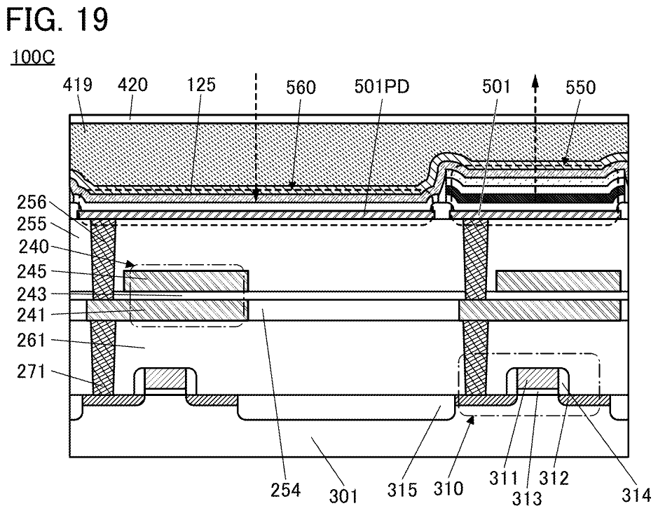

FIG. 18 is a cross-sectional view illustrating a structure example of a display device 100B and is a modification example of the display device 100A. The display device 100B differs from the display device 100A in that a substrate 153 instead of the substrate 151, an adhesive layer 155, and an insulating layer 212 are included and that a substrate 154 instead of the substrate 152, an adhesive layer 156, and an insulating layer 158 are included.

In the display device 100B, the substrate 153 and the insulating layer 212 are attached to each other with the adhesive layer 155. In addition, the substrate 154 and the insulating layer 158 are attached to each other with the adhesive layer 156.

When the display device 100B illustrated in FIG. 18 is manufactured, first, a first manufacture substrate provided with the insulating layer 212, each transistor, the light-emitting element 550, the light-receiving element 560, and the like and a second manufacture substrate provided with the insulating layer 158, the light-blocking layer 148, the filter 146, and the like are attached to each other with the adhesive layer 242. Then, the substrate 153 is attached to a surface where the first manufacture substrate is separated and exposed with the adhesive layer 155. Accordingly, each component formed over the first manufacture substrate is transferred onto the substrate 153. In addition, the substrate 154 is attached to a surface where the second manufacture substrate is separated and exposed with the adhesive layer 156. Accordingly, each component formed over the second manufacture substrate is transferred onto the substrate 154. Furthermore, the substrate 153 and the substrate 154 are preferably flexible. Accordingly, the display device 100B can be flexible. That is, the display device 100B can be a flexible display.

The inorganic insulating film that can be used for the insulating layer 211, the insulating layer 213, and the insulating layer 215 can be used for the insulating layer 212 and the insulating layer 158.

### Structure Example 3

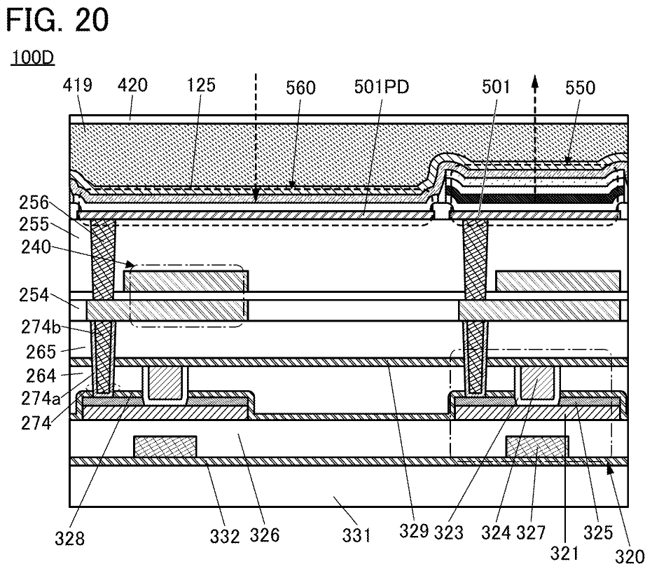

FIG. 19 is a cross-sectional view illustrating a structure example of a display device 100C. The display device 100C includes a substrate 301, the light-emitting element 550, the light-receiving element 560, a capacitor 240, and a transistor 310. The substrate 301 corresponds to the substrate 151 in FIG. 16, for example.

The transistor 310 is a transistor that includes a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance regions 312 are regions where the substrate 301 is doped with an impurity, and function as a source and a drain. The insulating layer 314 is provided to cover a side surface of the conductive layer 311.

In addition, an element isolation layer 315 is provided between two adjacent transistors 310 to be embedded in the substrate 301.

Furthermore, an insulating layer 261 is provided to cover the transistor 310, and the capacitor 240 is provided over the insulating layer 261.

The capacitor 240 includes a conductive layer 241, a conductive layer 245, and an insulating layer 243 between the conductive layer 241 and the conductive layer 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapped with the conductive layer 241 with the insulating layer 243 therebetween.

An insulating layer 255 is provided to cover the capacitor 240, and the light-emitting element 550, the light-receiving element 560, and the like are provided over the insulating layer 255. The protective layer 125 is provided over the light-emitting element 550 and the light-receiving element 560, and a substrate 420 is attached to the top surface of the protective layer 125 with a resin layer 419. The substrate 420 corresponds to the substrate 152 in FIG. 16, for example.

The electrode 501 of the light-emitting element 550 and the electrode 501PD of the light-receiving element 560 are electrically connected to the one of the source and the drain of the transistor 310 through a plug 256 embedded in the insulating layer 255 and the insulating layer 243, the conductive layer 241 embedded in the insulating layer 254, and the plug 271 embedded in the insulating layer 261.

### Structure Example 4

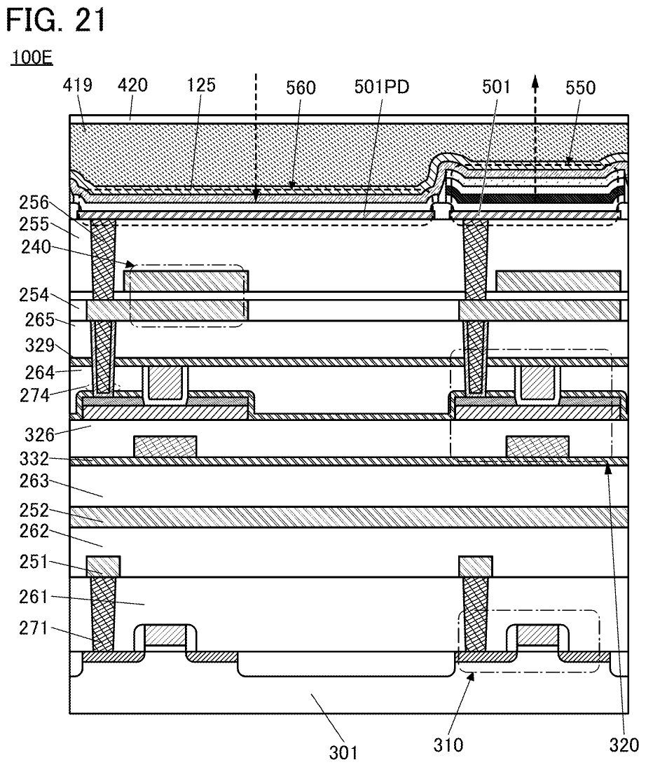

FIG. 20 is a cross-sectional view illustrating a structure example of a display device 100D. The display device 100D differs from the display device 100C mainly in a transistor structure. Note that the description of portions similar to those in the display device 100C is omitted in some cases.

A transistor 320 is a transistor that contains a metal oxide in a semiconductor layer where a channel is formed (hereinafter also referred to as an OS transistor).

The transistor 320 includes a semiconductor layer 321, an insulating layer 323, a conductive layer 324, a pair of conductive layers 325, an insulating layer 326, and a conductive layer 327.

A substrate 331 corresponds to the substrate 151 in FIG. 16, for example. As the substrate 331, an insulating substrate or a semiconductor substrate can be used.

An insulating layer 332 is provided over the substrate 331. The insulating layer 332 functions as a barrier layer that prevents diffusion of impurities such as water or hydrogen from the substrate 331 into the transistor 320 and release of oxygen from the semiconductor layer 321 to the insulating layer 332 side. For the insulating layer 332, for example, a film in which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used for at least part of the insulating layer 326 that is in contact with the semiconductor layer 321. A top surface of the insulating layer 326 is preferably planarized.

The semiconductor layer 321 is provided over the insulating layer 326. The semiconductor layer 321 preferably includes a film of a metal oxide that has semiconductor characteristics.

The pair of conductive layers 325 are provided on and in contact with the semiconductor layer 321 and function as a source electrode and a drain electrode.

In addition, an insulating layer 328 is provided to cover top surfaces and side surfaces of the pair of conductive layers 325, side surfaces of the semiconductor layer 321, and the like, and an insulating layer 264 is provided over the insulating layer 328. The insulating layer 328 functions as a barrier layer that prevents diffusion of impurities such as water or hydrogen from the insulating layer 264 and the like into the semiconductor layer 321 and release of oxygen from the semiconductor layer 321. For the insulating layer 328, an insulating film similar to the insulating layer 332 can be used.

An opening that reaches the semiconductor layer 321 is provided in the insulating layer 328 and the insulating layer 264. The insulating layer 323 that is in contact with side surfaces of the insulating layer 264, the insulating layer 328, and the conductive layer 325 and a top surface of the semiconductor layer 321 and the conductive layer 324 are embedded in the opening. The conductive layer 324 functions as a second gate electrode, and the insulating layer 323 functions as a second gate insulating layer.

A top surface of the conductive layer 324, a top surface of the insulating layer 323, and a top surface of the insulating layer 264 are planarized so that they are substantially level with each other, and an insulating layer 329 and an insulating layer 265 are provided to cover these layers.

The insulating layer 264 and the insulating layer 265 each function as an interlayer insulating layer. The insulating layer 329 functions as a barrier layer that prevents diffusion of impurities such as water or hydrogen from the insulating layer 265 and the like into the transistor 320. As the insulating layer 329, an insulating film similar to the insulating layer 328 and the insulating layer 332 can be used.

A plug 274 electrically connected to one of the pair of conductive layers 325 is provided to be embedded in the insulating layer 265, the insulating layer 329, the insulating layer 264, and the insulating layer 328. Here, the plug 274 preferably includes a conductive layer 274a that covers a side surface of an opening formed in the insulating layer 265, the insulating layer 329, the insulating layer 264, and the insulating layer 328 and part of a top surface of the conductive layer 325, and a conductive layer 274b in contact with a top surface of the conductive layer 274a. At this time, a conductive material in which hydrogen and oxygen are less likely to diffuse is preferably used for the conductive layer 274a.

The structures of the insulating layer 254 and components thereover up to the substrate 420 in the display device 100D are similar to those in the display device 100C.

### Structure Example 5

FIG. 21 is a cross-sectional view illustrating a structure example of a display device 100E. The display device 100E has a structure in which the transistor 310 whose channel is formed in the substrate 301 and the transistor 320 including a metal oxide in the semiconductor layer where the channel is formed are stacked. Note that the description of portions similar to those in the display device 100C or the display device 100D is omitted in some cases.

The insulating layer 261 is provided to cover the transistor 310, and a conductive layer 251 is provided over the insulating layer 261. In addition, an insulating layer 262 is provided to cover the conductive layer 251, and a conductive layer 252 is provided over the insulating layer 262. The conductive layer 251 and the conductive layer 252 each function as a wiring. Furthermore, an insulating layer 263 and the insulating layer 332 are provided to cover the conductive layer 252, and the transistor 320 is provided over the insulating layer 332. Moreover, the insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in a pixel circuit. In addition, the transistor 310 can be used as a transistor included in a pixel circuit or a transistor included in a driver circuit for driving the pixel circuit (a gate line driver circuit or a source line driver circuit). Furthermore, the transistor 310 and the transistor 320 can be used as transistors included in a variety of circuits such as an arithmetic circuit and a memory circuit.

With such a structure, not only the pixel circuit but also, for example, the driver circuit can be formed directly under the light-emitting element; thus, the display device can be downsized as compared with the case where the driver circuit is provided around a display portion.

At least part of the structure examples, the drawings corresponding thereto, and the like illustrated in this embodiment can be combined with the other structure examples, the other drawings, and the like as appropriate.

At least part of this embodiment can be implemented in combination with the other embodiments described in this specification as appropriate.

### Embodiment 3

In this embodiment, a metal oxide that can be used in the OS transistor described in the above embodiment is described.

A metal oxide preferably contains at least indium or zinc. In particular, indium and zinc are preferably contained. In addition, in addition to these, aluminum, gallium, yttrium, tin, or the like is preferably contained. Furthermore, one or more kinds selected from boron, silicon, titanium, iron, nickel, germanium, zirconium, molybdenum, lanthanum, cerium, neodymium, hafnium, tantalum, tungsten, magnesium, cobalt, and the like may be contained.

In addition, the metal oxide can be formed by a sputtering method, a CVD method such as an MOCVD method, an ALD method, or the like.

### <Classification of Crystal Structure>

Amorphous (including completely amorphous), CAAC (c-axis-aligned crystalline), nc (nanocrystalline), CAC (cloud-aligned composite), single-crystal, and polycrystalline (polycrystal) structures can be given as examples of a crystal structure of an oxide semiconductor.

Note that the crystal structure of a film or a substrate can be evaluated with an X-ray diffraction (XRD) spectrum. For example, evaluation is possible using an XRD spectrum that is obtained by GIXD (Grazing-Incidence XRD) measurement. Note that a GIXD method is also referred to as a thin film method or a Seemann-Bohlin method.

For example, the XRD spectrum of a quartz glass substrate shows a peak with a substantially bilaterally symmetrical shape. On the other hand, the peak of the XRD spectrum of an IGZO film having a crystal structure has a bilaterally asymmetrical shape. The bilaterally asymmetrical peak of the XRD spectrum clearly shows the existence of crystal in the film or the substrate. In other words, the crystal structure of the film or the substrate cannot be regarded as an amorphous state unless it has a bilaterally symmetrical peak in the XRD spectrum.

In addition, the crystal structure of a film or a substrate can also be evaluated with a diffraction pattern obtained by a nanobeam electron diffraction method (NBED) (such a pattern is also referred to as a nanobeam electron diffraction pattern). For example, a halo pattern is observed in the diffraction pattern of the quartz glass substrate, which indicates that the quartz glass substrate is in an amorphous state. Furthermore, not a halo pattern but a spot-like pattern is observed in the diffraction pattern of the IGZO film deposited at room temperature. Thus, it is suggested that the IGZO film deposited at room temperature is in an intermediate state, which is neither a crystal state nor an amorphous state, and it cannot be concluded that the IGZO film is in an amorphous state.

### <<Structure of Oxide Semiconductor>>

Note that oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the CAAC-OS and the nc-OS. Other examples of the non-single-crystal oxide semiconductor include a polycrystalline oxide semiconductor, an amorphous-like oxide semiconductor (a-like OS), an amorphous oxide semiconductor, and the like.

Here, the CAAC-OS, the nc-OS, and the a-like OS are described in detail.

### [CAAC-OS]

The CAAC-OS is an oxide semiconductor that has a plurality of crystal regions each of which has c-axis alignment in a particular direction. Note that the particular direction refers to the thickness direction of a CAAC-OS film, the normal direction of a surface where the CAAC-OS film is formed, or the normal direction of the surface of the CAAC-OS film. In addition, the crystal region refers to a region having periodic atomic arrangement. Note that when atomic arrangement is regarded as lattice arrangement, the crystal region also refers to a region with uniform lattice arrangement. Furthermore, the CAAC-OS has a region where a plurality of crystal regions are connected in an a-b plane direction, and the region has distortion in some cases. Note that distortion refers to a portion where the direction of lattice arrangement changes between a region with uniform lattice arrangement and another region with uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one fine crystal, the maximum diameter of the crystal region is less than 10 nm. Alternatively, in the case where the crystal region is formed of a large number of fine crystals, the size of the crystal region is sometimes approximately several tens of nanometers.

In addition, in an In-M-Zn oxide (the element M is one or more kinds selected from aluminum, gallium, yttrium, tin, titanium, and the like), the CAAC-OS tends to have a layer-shaped crystal structure (also referred to as a layer-shaped structure) in which a layer containing indium (In) and oxygen (hereinafter an In layer) and a layer containing the element M, zinc (Zn), and oxygen (hereinafter an (M,Zn) layer) are stacked. Note that indium and the element M can be replaced with each other. Therefore, indium is sometimes contained in the (M,Zn) layer. Furthermore, the element M is sometimes contained in the In layer. Note that Zn is sometimes contained in the In layer. Such a layer-shaped structure is observed as a lattice image in a high-resolution TEM (Transmission Electron Microscope) image, for example.

When the CAAC-OS film is subjected to structural analysis by out-of-plane XRD measurement with an XRD apparatus using θ/2θ scanning, for example, a peak indicating c-axis alignment is detected at 2θ of 31θ or around 31°. Note that the position of the peak indicating c-axis alignment (the value of 2θ) might fluctuate depending on the kind, composition, or the like of the metal element contained in the CAAC-OS.

In addition, for example, a plurality of bright spots are observed in the electron diffraction pattern of the CAAC-OS film. Note that one spot and another spot are observed point-symmetrically with a spot of an incident electron beam passing through a sample (also referred to as a direct spot) as a symmetric center.

When the crystal region is observed from the particular direction, lattice arrangement in the crystal region is basically hexagonal lattice arrangement; however, a unit lattice is not always a regular hexagon and is a non-regular hexagon in some cases. In addition, pentagonal lattice arrangement, heptagonal lattice arrangement, and the like are included in the distortion in some cases. Note that a clear grain boundary cannot be observed even in the vicinity of the distortion in the CAAC-OS. That is, it is found that formation of a grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, and the like.

Note that a crystal structure in which a clear grain boundary is observed is what is called polycrystal. It is highly probable that the grain boundary becomes a recombination center and captures carriers and thus decreases the on-state current and field-effect mobility of a transistor, for example. Thus, the CAAC-OS in which no clear grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a grain boundary as compared with an In oxide.

The CAAC-OS is an oxide semiconductor with high crystallinity in which no clear grain boundary is observed. Thus, in the CAAC-OS, it can be said that a reduction in electron mobility due to the grain boundary is unlikely to occur. In addition, entry of impurities, formation of defects, or the like might decrease the crystallinity of an oxide semiconductor. This means that the CAAC-OS can also be referred to as an oxide semiconductor having small amounts of impurities and defects (oxygen vacancies or the like). Therefore, physical properties of an oxide semiconductor including the CAAC-OS become stable. Accordingly, the oxide semiconductor including the CAAC-OS is resistant to heat and has high reliability. In addition, the CAAC-OS is also stable with respect to high temperatures in the manufacturing process (what is called thermal budget). Accordingly, the use of the CAAC-OS for the OS transistor can extend the degree of freedom of the manufacturing process.

### [Nc-OS]

In the nc-OS, a microscopic region (e.g., a region greater than or equal to 1 nm and less than or equal to 10 nm, in particular, a region greater than or equal to 1 nm and less than or equal to 3 nm) has periodic atomic arrangement. In other words, the nc-OS includes a fine crystal. Note that the size of the fine crystal is, for example, greater than or equal to 1 nm and less than or equal to 10 nm, particularly greater than or equal to 1 nm and less than or equal to 3 nm; thus, the fine crystal is also referred to as a nanocrystal. In addition, there is no regularity of crystal orientation between different nanocrystals in the nc-OS. Hence, the orientation in the whole film is not observed. Accordingly, in some cases, the nc-OS cannot be distinguished from an a-like OS or an amorphous oxide semiconductor, depending on the analysis method. For example, when an nc-OS film is subjected to structural analysis by out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are obtained in the observed electron diffraction pattern when the nc-OS film is subjected to electron diffraction (also referred to as nanobeam electron diffraction) using an electron beam with a probe diameter close to or smaller than the size of a nanocrystal (e.g., greater than or equal to 1 nm and less than or equal to 30 nm).

### [A-Like OS]

The a-like OS is an oxide semiconductor having a structure between those of the nc-OS and the amorphous oxide semiconductor. The a-like OS has a void or a low-density region. That is, the a-like OS has lower crystallinity than the nc-OS and the CAAC-OS. Moreover, the a-like OS has higher hydrogen concentration in the film than the nc-OS and the CAAC-OS.

### <<Composition of Oxide Semiconductor>>

Next, the CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic ratios of In, Ga, and Zn to the metal elements contained in the CAC-OS in an In—Ga—Zn oxide are denoted by [In], [Ga], and [Zn], respectively. For example, the first region in the CAC-OS in the In—Ga—Zn oxide has [In] higher than that in the composition of the CAC-OS film. Moreover, the second region has [Ga] higher than that in the composition of the CAC-OS film. Alternatively, for example, the first region has higher [In] and lower [Ga] than the second region. Moreover, the second region has higher [Ga] and lower [In] than the first region.

Specifically, the first region includes indium oxide, indium zinc oxide, or the like as its main component. In addition, the second region includes gallium oxide, gallium zinc oxide, or the like as its main component. That is, the first region can be referred to as a region containing In as its main component. Furthermore, the second region can be referred to as a region containing Ga as its main component.

Note that a clear boundary between the first region and the second region cannot be observed in some cases.

In addition, in a material composition of a CAC-OS in an In—Ga—Zn oxide that contains In, Ga, Zn, and O, there are regions containing Ga as a main component in part of the CAC-OS and regions containing In as a main component in another part of the CAC-OS. These regions each form a mosaic pattern and are randomly present. Thus, it is suggested that the CAC-OS has a structure in which metal elements are unevenly distributed.

The CAC-OS can be formed by a sputtering method under a condition where a substrate is not heated intentionally, for example. Furthermore, in the case where the CAC-OS is formed by a sputtering method, any one or more selected from an inert gas (typically, argon), an oxygen gas, and a nitrogen gas is used as a deposition gas. Moreover, the ratio of the flow rate of an oxygen gas to the total flow rate of the deposition gas at the time of deposition is preferably as low as possible, and for example, the ratio of the flow rate of an oxygen gas to the total flow rate of the deposition gas at the time of deposition is preferably higher than or equal to 0% and lower than 30%, further preferably higher than or equal to 0% and lower than or equal to 10%.

For example, energy dispersive X-ray spectroscopy (EDX) is used to obtain EDX mapping, and according to the EDX mapping, the CAC-OS in the In—Ga—Zn oxide has a structure in which the region containing In as its main component (the first region) and the region containing Ga as its main component (the second region) are unevenly distributed and mixed.

Here, the first region has higher conductivity than the second region. In other words, when carriers flow through the first region, the conductivity of a metal oxide is exhibited. Accordingly, when the first regions are distributed in a metal oxide like a cloud, high field-effect mobility (μ) can be achieved.

In contrast, the second region has a higher insulating property than the first region. In other words, when the second regions are distributed in a metal oxide, leakage current can be inhibited.

In the case where the CAC-OS is used for a transistor, a switching function (On/Off function) can be given to the CAC-OS owing to the complementary action of the conductivity derived from the first region and the insulating property derived from the second region. That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, high on-state current (Iₒₙ), high field-effect mobility (μ), and excellent switching operation can be achieved.

In addition, a transistor using the CAC-OS has high reliability. Thus, the CAC-OS is most suitable for a variety of semiconductor devices such as display devices.

Oxide semiconductors have various structures and each have different properties. Two or more kinds among the amorphous oxide semiconductor, the polycrystalline oxide semiconductor, the a-like OS, the CAC-OS, the nc-OS, and the CAAC-OS may be included in an oxide semiconductor according to one embodiment of the present invention.

### <Transistor Including Oxide Semiconductor>

Next, the case where the oxide semiconductor is used for a transistor is described.

When the oxide semiconductor is used for a transistor, a transistor with high field-effect mobility can be achieved. In addition, a highly reliable transistor can be achieved.

An oxide semiconductor having a low carrier concentration is preferably used for the transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. Note that in the case where the carrier concentration of an oxide semiconductor film is lowered, the impurity concentration in the oxide semiconductor film is lowered to decrease the density of defect states. In this specification and the like, a state with a low impurity concentration and a low density of defect states is referred to as a highly purified intrinsic or substantially highly purified intrinsic state. Note that an oxide semiconductor having a low carrier concentration is sometimes referred to as a highly purified intrinsic or substantially highly purified intrinsic oxide semiconductor.

In addition, a highly purified intrinsic or substantially highly purified intrinsic oxide semiconductor film has a low density of defect states and accordingly has a low density of trap states in some cases.

In addition, electric charge captured by the trap states in an oxide semiconductor takes a long time to disappear and might behave like fixed electric charge. Thus, a transistor whose channel formation region is formed in an oxide semiconductor having a high density of trap states has unstable electrical characteristics in some cases.

Accordingly, in order to stabilize electrical characteristics of the transistor, reducing the concentration in the oxide semiconductor is effective. In addition, in order to reduce the impurity concentration in the oxide semiconductor, the impurity concentration in a film that is adjacent to the oxide semiconductor is also preferably reduced. Examples of impurities include hydrogen, nitrogen, an alkali metal, an alkaline earth metal, iron, nickel, silicon, and the like.

### <Impurities>

Here, the influence of each impurity in the oxide semiconductor is described.

When silicon or carbon, which is a Group 14 element, is contained in an oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration obtained by secondary ion mass spectrometry (SIMS)) are each set lower than or equal to 2×10¹⁸ atoms/cm³, preferably lower than or equal to 2×10¹⁷ atoms/cm³.

In addition, when the oxide semiconductor contains an alkali metal or an alkaline earth metal, defect states are formed and carriers are generated in some cases. Accordingly, a transistor using an oxide semiconductor that contains an alkali metal or an alkaline earth metal tends to have normally-on characteristics. Thus, the concentration of an alkali metal or an alkaline earth metal in the oxide semiconductor that is obtained by SIMS is lower than or equal to 1×10¹⁸ atoms/cm³, preferably lower than or equal to 2×10¹⁶ atoms/cm³.

In addition, an oxide semiconductor containing nitrogen easily becomes n-type by generation of electrons serving as carriers and an increase in carrier concentration. Thus, a transistor using an oxide semiconductor that contains nitrogen as the semiconductor tends to have normally-on characteristics. Alternatively, when nitrogen is contained in the oxide semiconductor, a trap state is sometimes formed. This might make the electrical characteristics of the transistor unstable. Therefore, the concentration of nitrogen in the oxide semiconductor that is obtained by SIMS is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

In addition, hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, in some cases, some hydrogen is bonded to oxygen bonded to a metal atom and generates an electron serving as a carrier. Thus, a transistor using an oxide semiconductor that contains hydrogen tends to have normally-on characteristics. For this reason, hydrogen in the oxide semiconductor is preferably reduced as much as possible. Specifically, the hydrogen concentration in the oxide semiconductor that is obtained by SIMS is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for a channel formation region in a transistor, the transistor can have stable electrical characteristics.

At least part of this embodiment can be implemented in combination with the other embodiments described in this specification as appropriate.

### Embodiment 4

In this embodiment, electronic devices each including a display device according to one embodiment of the present invention will be described.

The display device according to one embodiment of the present invention can be provided in a variety of electronic devices. For example, the display device according to one embodiment of the present invention can be provided in a digital camera, a digital video camera, a digital photo frame, a portable game machine, a portable information terminal, an audio reproducing device, or the like, in addition to an electronic device with a comparatively large screen, such as a television device, a desktop or laptop computer, a tablet computer, a monitor for a computer or the like, digital signage, or a large game machine such as a pachinko machine.

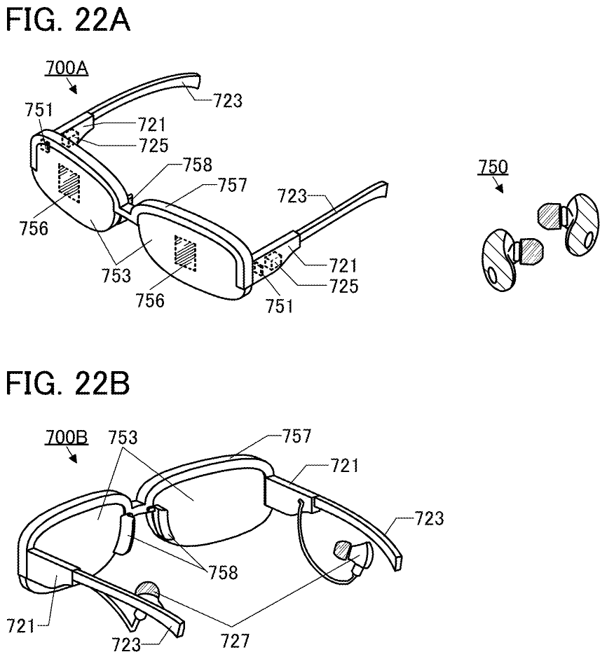

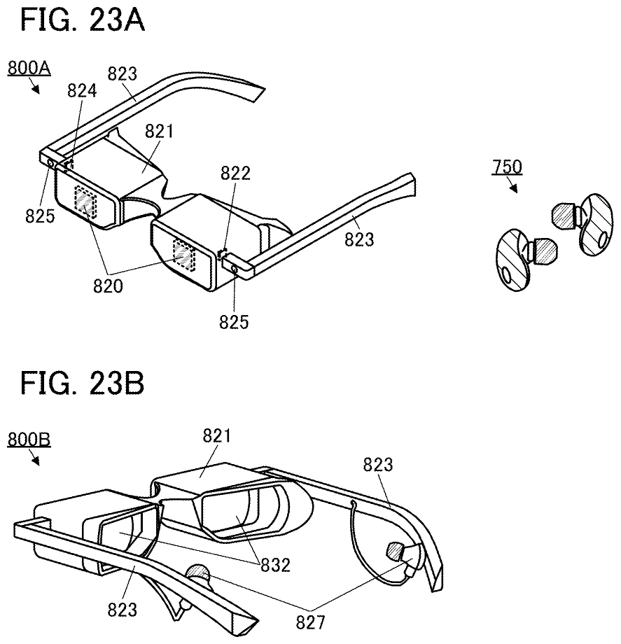

Examples of wearable devices that can be worn on the head are described using FIG. 22A, FIG. 22B, FIG. 23A, and FIG. 23B. These wearable devices have one or both of a function of displaying AR (Augmented Reality) contents and a function of displaying VR (Virtual Reality) contents. Note that these wearable devices may have a function of displaying SR (Substitutional Reality) or MR (Mixed Reality) contents, in addition to AR and VR contents. An electronic device having a function of displaying contents of AR, VR, SR, MR, or the like enables the user of the electronic device to reach a higher sense of immersion.

An electronic device 700A illustrated in FIG. 22A and an electronic device 700B illustrated in FIG. 22B each include a pair of display panels 751, a pair of housings 721, a communication portion (not illustrated), a pair of wearing portions 723, a control portion (not illustrated), a sensor portion 725, a pair of optical members 753, a frame 757, and a pair of nose pads 758. The sensor portion 725 can be provided in the housing 721, for example.

The display device according to one embodiment of the present invention can be used for the display panel 751. Thus, the electronic device can perform display with extremely high definition.

The electronic device 700A and the electronic device 700B can each project an image displayed on the display panel 751 onto a display region 756 of the optical member 753. Since the optical members 753 have a light-transmitting property, a user can see images displayed on the display regions that are superimposed on transmission images seen through the optical members 753. Accordingly, each of the electronic device 700A and the electronic device 700B is an electronic device capable of AR display.

In each of the electronic device 700A and the electronic device 700B, a camera capable of capturing images of the front side may be provided as an image capturing portion. Furthermore, when each of the electronic device 700A and the electronic device 700B is provided with an acceleration sensor such as a gyroscope sensor, the orientation of the user's head can be sensed and an image corresponding to the orientation can be displayed on the display region 756.

The communication portion includes a wireless communication device, and for example, a video signal can be supplied by the wireless communication device. Note that instead of or in addition to the wireless communication device, a connector to which a cable for supplying a video signal and a power supply potential can be connected may be provided.

In addition, each of the electronic device 700A and the electronic device 700B is provided with a battery so that each of the electronic device 700A and the electronic device 700B can be charged wirelessly and/or by wire.

The sensor portion 725 has a function of detecting a touch on an outer surface of the housing 721, for example. Detecting a tap operation, a slide operation, or the like by the user with the sensor portion 725 enables a variety of processings. For example, processing such as a pause and a restart of a moving image can be executed by a tap operation, and processing such as fast forward and fast rewind can be executed by a slide operation. In addition, the sensor portion 725 is provided in each of the two housings 721, so that the range of the operation can be increased.

The display device according to one embodiment of the present invention can be employed for the sensor portion 725. Specifically, a light-receiving element that can be included in the display device according to one embodiment of the present invention can be provided in the sensor portion 725. In addition, the light-receiving element can be manufactured in the sensor portion 725 by a method for manufacturing the display device according to one embodiment of the present invention. Accordingly, the sensor portion 725 can be a touch sensor that includes a light-receiving element with a high aperture ratio. Therefore, the sensor portion 725 can be a touch sensor with high detection accuracy.

An electronic device 800A illustrated in FIG. 23A and an electronic device 800B illustrated in FIG. 23B each include a pair of display portions 820, a housing 821, a communication portion 822, a pair of wearing portions 823, a control portion 824, a pair of image capturing portions 825, and a pair of lenses 832.

A display device according to one embodiment of the present invention can be employed in the display portion 820. Thus, the electronic device can perform display with extremely high definition. This enables a user to feel a high sense of immersion.

The display portion 820 are positioned inside the housing 821 to be seen through the lenses 832. Furthermore, when the pair of display portions 820 display different images, 3D display using parallax can also be performed.

Each of the electronic device 800A and the electronic device 800B can be regarded as an electronic device for VR. The user who wears the electronic device 800A or the electronic device 800B can see images displayed on the display portions 820 through the lenses 832.

The electronic device 800A and the electronic device 800B each preferably include a mechanism for adjusting the lateral positions of the lenses 832 and the display portions 820 so that the lenses 832 and the display portions 820 are positioned optimally in accordance with the positions of the user's eyes. In addition, a mechanism for adjusting focus by changing the distance between the lens 832 and the display portion 820 is preferably included.

The electronic device 800A or the electronic device 800B can be worn on the user's head with the wearing portions 823. Note that FIG. 23A illustrates an example where the wearing portion 823 has a shape like a temple of glasses (also referred to as a joint or the like); however, one embodiment of the present invention is not limited thereto. The wearing portion 823 can have any shape with which the user can wear and can have a shape of a helmet or a band, for example.

The image capturing portion 825 has a function of obtaining external information. Data obtained by the image capturing portion 825 can be output to the display portion 820. A light-receiving element that can be included in the display device according to one embodiment of the present invention can be provided in the image capturing portion 825. In addition, the light-receiving element can be manufactured in the image capturing portion 825 by the method for manufacturing the display device according to one embodiment of the present invention. Accordingly, a light-receiving element with a high aperture ratio can be provided in the image capturing portion 825, so that the image capturing portion 825 can perform image capturing with high sensitivity. Therefore, the image capturing portion 825 can perform image capturing with a high S/N ratio even at low illuminance, for example.

Note that although an example where the image capturing portion 825 is included is shown here, a range sensor that is capable of measuring a distance between the user and an object (hereinafter such a sensor is also referred to as a sensing portion) is provided. In other words, the image capturing portion 825 is one embodiment of the sensing portion. For the sensing portion, an image sensor or a distance image sensor such as LIDAR (Light Detection and Ranging) can be used, for example. By using images obtained by a camera and images obtained by the distance image sensor, more information can be obtained and a gesture operation with higher accuracy is possible.

The electronic device 800A may include a vibration mechanism that functions as bone-conduction earphones. For example, a structure in which the vibration mechanism is included can be applied to any one or more of the display portion 820, the housing 821, and the wearing portion 823. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying, for example, a video signal from a video output device, power for charging a battery provided in the electronic device, and the like can be connected.

An electronic device according to one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 22A has a function of transmitting information to the earphones 750 with the wireless communication function. As another example, the electronic device 800A illustrated in FIG. 23A has a function of transmitting information to the earphones 750 with the wireless communication function.

Alternatively, the electronic device may include an earphone portion. The electronic device 700B illustrated in FIG. 22B includes earphone portions 727. For example, a structure in which the earphone portions 727 and the control portion are connected to each other by wire can be employed. Part of a wiring that connects the earphone portions 727 and the control portion may be positioned inside the housing 721 or the wearing portion 723.

Similarly, the electronic device 800B illustrated in FIG. 23B includes earphone portions 827. For example, a structure in which the earphone portions 827 and the control portion 824 are connected to each other by wire can be employed. Part of a wiring that connects the earphone portions 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

Note that the electronic device may include an audio output terminal to which earphones, headphones, or the like can be connected. Alternatively, the electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (the electronic device 700A, the electronic device 700B, or the like) and the goggles-type device (the electronic device 800A, the electronic device 800B, or the like) are suitable for the electronic device according to one embodiment of the present invention.

In addition, the electronic device according to one embodiment of the present invention can transmit information to earphones by wire or wirelessly.

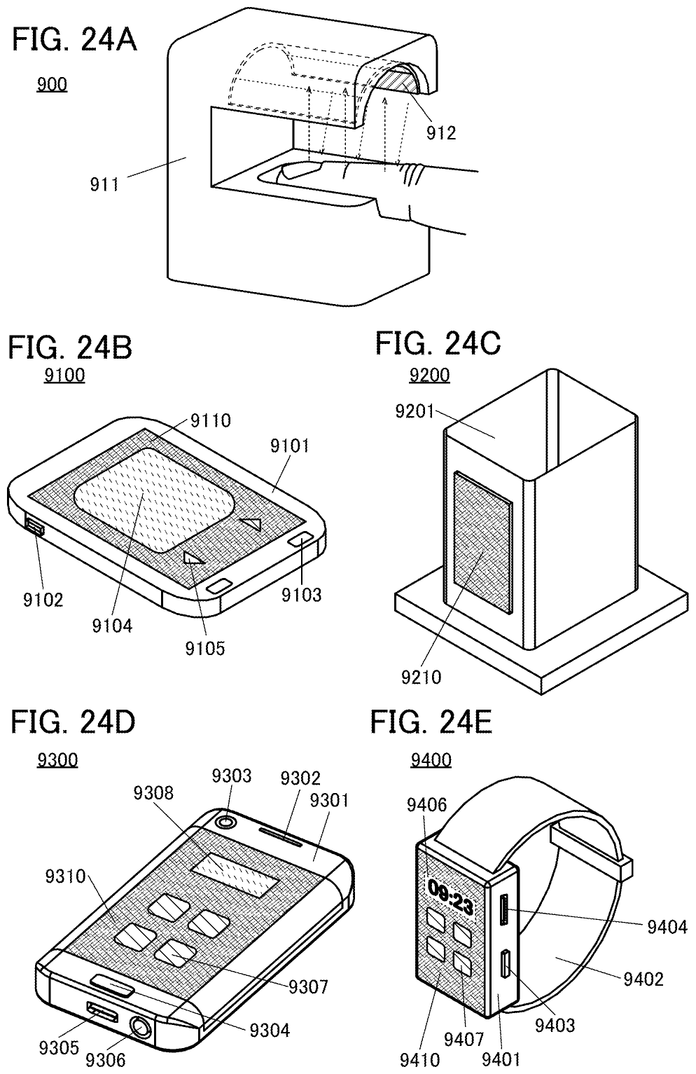

FIG. 24A is a diagram illustrating an example of an oximeter 900. The oximeter 900 includes a housing 911 and a light-emitting and receiving device 912. The housing 911 is provided with a cavity portion, and the light-emitting and receiving device 912 is provided to be in contact with a wall surface of the cavity portion.

The light-emitting and receiving device 912 has a function of a light source that emits light and a function of a sensor that detects light. For example, in the case where an object is put in the cavity portion of the housing 911, the light-emitting and receiving device 912 emits light, the object is irradiated with emitted light, and light reflected by the object can be detected by the light-emitting and receiving device 912.

Here, the color of blood is changed depending on oxygen saturation of hemoglobin contained in the blood (the percentage of oxygen-bound hemoglobin). Thus, in the case where a finger is put in the cavity portion of the housing 911, the intensity of light reflected by the finger that is detected by the light-emitting and receiving device 912 is changed. For example, the intensity of red light that is detected by the light-emitting and receiving device 912 is changed. Accordingly, the oximeter 900 can measure oxygen saturation through detection of the intensity of reflected light by the light-emitting and receiving device 912. The oximeter 900 can be a pulse oximeter, for example.

The display device according to one embodiment of the present invention can be employed in the light-emitting and receiving device 912. In that case, the light-emitting and receiving device 912 includes at least a light-emitting element that emits red light (R). In addition, the light-emitting and receiving device 912 preferably includes a light-emitting element that emits infrared light (IR). There is a large difference between the red light (R) reflectance of oxygen-bound hemoglobin and the red light (R) reflectance of oxygen-unbound hemoglobin. On the other hand, there is a small difference between the infrared light (IR) reflectance of oxygen-bound hemoglobin and the infrared light (IR) reflectance of oxygen-unbound hemoglobin. Therefore, the light-emitting and receiving device 912 includes not only a light-emitting element that emits red light (R) but also a light-emitting element that emits infrared light (IR), so that the oximeter 900 can measure oxygen saturation with high accuracy.

In the case where the display device according to one embodiment of the present invention is employed as the light-emitting and receiving device 912, the light-emitting and receiving device 912 is preferably flexible. When the light-emitting and receiving device 912 is flexible, the light-emitting and receiving device 912 can have a curved shape. Accordingly, for example, the finger can be irradiated with light uniformly, and oxygen saturation can be measured with high accuracy, for example.

FIG. 24B is a diagram illustrating an example of a portable data terminal 9100. The portable data terminal 9100 includes a display portion 9110, a housing 9101, a key 9102, a speaker 9103, and the like. The portable data terminal 9100 can be a tablet, for example. Here, the key such as the key 9102 can be a key for switching the on/off of a power source. That is, the key such as the key 9102 can be a power switch, for example. Alternatively, the key such as the key 9102 can be an operation key to be used to make an electronic device perform a desired operation, for example.

The display portion 9110 can display information 9104, operation buttons (also referred to as operation icons or simply icons) 9105, and the like.

When the display device according to one embodiment of the present invention is provided in the portable data terminal 9100, the display portion 9110 can have a function of a touch sensor or a near touch sensor.

FIG. 24C is a diagram illustrating an example of digital signage 9200. The digital signage 9200 can have a structure where a display portion 9210 is attached to a column 9201.

When the display device according to one embodiment of the present invention is provided in the digital signage 9200, the display portion 9210 can have a function of a touch sensor or a near touch sensor.

FIG. 24D is a diagram illustrating an example of a portable information terminal 9300. The portable information terminal 9300 includes a display portion 9310, a housing 9301, a speaker 9302, a camera 9303, a key 9304, a connection terminal 9305, a connection terminal 9306, and the like. For example, the portable information terminal 9300 can be a smartphone. Note that the connection terminal 9305 can be a micro USB terminal, a lightning terminal, or a Type-C terminal, or the like, for example. In addition, the connection terminal 9306 can be an earphone jack, for example.

The display portion 9310 can display, for example, an operation button 9307. The display portion 9310 can also display information 9308. Examples of the information 9308 include display indicating incoming e-mails, SNS (social networking services), phone calls, and the like; the titles of e-mails, SNS, and the like; the senders of e-mails, SNS, and the like; dates; time; remaining battery; radio field strength; and the like.

When the display device according to one embodiment of the present invention is provided in the portable information terminal 9300, the display portion 9310 can have a function of a touch sensor or a near touch sensor.

FIG. 24E is a diagram illustrating an example of a wristwatch-type portable information terminal 9400. The portable information terminal 9400 includes a display portion 9410, a housing 9401, a wristband 9402, a key 9403, a connection terminal 9404, and the like. Note that the connection terminal 9404 can be a micro USB terminal, a lightning terminal, or a Type-C terminal, or the like, for example, like the connection terminal 9305 or the like.

The display portion 9410 can display information 9406, operation buttons 9407, and the like. FIG. 24E illustrates an example in which time is displayed on the display portion 9410 as the information 9406.

When the display device according to one embodiment of the present invention is provided in the portable information terminal 9400, the display portion 9410 can have a function of a touch sensor or a near touch sensor.

At least part of the structure examples, the drawings corresponding thereto, and the like illustrated in this embodiment can be combined with the other structure examples, the other drawings, and the like as appropriate.

At least part of this embodiment can be implemented in combination with the other embodiments described in this specification as appropriate.

### REFERENCE NUMERALS

10: display device, 10A: display device, 10B: display device, 20: pixel, 51: substrate, 52: finger, 53: layer, 55: layer, 57: layer, 59: substrate, 65: region, 67: fingerprint, 69: contact portion, 71: layer, 73: light-blocking layer, 75: light, 77: light, 80: light-receiving range, 81: light-receiving range, 100: display device, 100A: display device, 100B: display device, 100C: display device, 100D: display device, 100E: display device, 101: substrate, 125: protective layer, 130: connection portion, 131: insulating layer, 141: transistor, 141a: sacrificial film, 141b: sacrificial film, 142: transistor, 143: space, 143a: protective film, 143b: protective film, 145a: resist mask, 145b: resist mask, 146: filter, 147a: sacrificial layer, 147b: sacrificial layer, 147c: sacrificial layer, 147d: sacrificial layer, 148: light-blocking layer, 149a: protective layer, 149b: protective layer, 151: substrate, 152: substrate, 153: substrate, 154: substrate, 155: adhesive layer, 156: adhesive layer, 158: insulating layer, 162: display portion, 164: circuit, 165: wiring, 166: conductive layer, 172: FPC, 173: IC, 201: transistor, 204: connection portion, 211: insulating layer, 212: insulating layer, 213: insulating layer, 214: insulating layer, 215: insulating layer, 221: conductive layer, 222a: conductive layer, 222b: conductive layer, 223: conductive layer, 228: region, 231: semiconductor layer, 240: capacitor, 241: conductive layer, 242: adhesive layer, 243: insulating layer, 244: connection layer, 245: conductive layer, 251: conductive layer, 252: conductive layer, 254: insulating layer, 255: insulating layer, 256: plug, 261: insulating layer, 262: insulating layer, 263: insulating layer, 264: insulating layer, 265: insulating layer, 271: plug, 274: plug, 274a: conductive layer, 274b: conductive layer, 301: substrate, 310: transistor, 311: conductive layer, 312: low-resistance region, 313: insulating layer, 314: insulating layer, 315: element isolation layer, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 419: resin layer, 420: substrate, 501: electrode, 501B: electrode, 501C: connection electrode, 501G: electrode, 501IR: electrode, 501PD: electrode, 501R: electrode, 502: electrode, 503: region, 512: light-emitting unit, 512B: light-emitting unit, 512B_1: light-emitting unit, 512B_2: light-emitting unit, 512B_3: light-emitting unit, 512G: light-emitting unit, 512G_1: light-emitting unit, 512G_2: light-emitting unit, 512G_3: light-emitting unit, 512Gf_1: layer, 512Gf_2: layer, 512IR_1: light-emitting unit, 512IR_2: light-emitting unit, 512R: light-emitting unit, 512R_1: light-emitting unit, 512R_2: light-emitting unit, 512R_3: light-emitting unit, 512Rf_1: layer, 512Rf_2: layer, 521: layer, 522: layer, 523: light-emitting layer, 523B: light-emitting layer, 523G: light-emitting layer, 523R: light-emitting layer, 524: layer, 525: layer, 525B: layer, 525G: layer, 525Gf: film, 525IR: layer, 525R: layer, 525Rf: film, 531: intermediate layer, 531B: intermediate layer, 531G: intermediate layer, 531Gf: intermediate film, 531IR: intermediate layer, 531PD: intermediate layer, 531R: intermediate layer, 531Rf: intermediate film, 541: insulating layer, 542: light-receiving unit, 542_1: light-receiving unit, 542_2: light-receiving unit, 543: light-receiving layer, 544: insulating layer, 550: light-emitting element, 550B: light-emitting element, 550G: light-emitting element, 550IR: light-emitting element, 550R: light-emitting element, 560: light-receiving element, 560L: light-receiving element, 700A: electronic device, 700B: electronic device, 721: housing, 723: wearing portion, 725: sensor portion, 727: earphone portion, 750: earphone, 751: display panel, 753: optical member, 756: display region, 757: frame, 758: nose pad, 800A: electronic device, 800B: electronic device, 820: display portion, 821: housing, 822: communication portion, 823: wearing portion, 824: control portion, 825: image capturing portion, 827: earphone portion, 832: lens, 900: oximeter, 911: housing, 912: light-emitting and receiving device, 9100: portable data terminal, 9101: housing, 9102: key, 9103: speaker, 9104: information, 9110: display portion, 9200: digital signage, 9201: column, 9210: display portion, 9300: portable information terminal, 9301: housing, 9302: speaker, 9303: camera, 9304: key, 9305: connection terminal, 9306: connection terminal, 9307: operation button, 9308: information, 9310: display portion, 9400: portable information terminal, 9401: housing, 9402: wristband, 9403: key, 9404: connection terminal, 9406: information, 9407: operation button, and 9410: display portion.

1. A display device comprising:
a light-emitting element; and
a light-receiving element,
wherein the light-emitting element comprises:
a first pixel electrode;
a first light-emitting layer over the first pixel electrode;
an intermediate layer over the first light-emitting layer;
a second light-emitting layer over the intermediate layer;
a common layer over the second light-emitting layer; and
a common electrode over the common layer,
wherein the light-receiving element comprises:
a second pixel electrode;
a light-receiving layer over the second pixel electrode;
the common layer over the light-receiving layer; and
the common electrode over the common layer,
wherein in the light-emitting element, the common layer is configured to serve as one of a hole-injection layer and an electron-injection layer, and
wherein in the light-receiving element, the common layer is configured to serve as the one of a hole-transport layer and an electron-transport layer.

2. The display device according to claim 1, wherein the first light-emitting layer and the second light-emitting layer are configured to emit light of the same color.

3. The display device according to claim 1, further comprising a first transistor and a second transistor,
wherein one of a source and a drain of the first transistor is electrically connected to the first pixel electrode,
wherein one of a source and a drain of the second transistor is electrically connected to the second pixel electrode, and
wherein the first transistor and the second transistor contain silicon in a channel formation region.

4. The display device according to claim 1, further comprising a first transistor and a second transistor,
wherein one of a source and a drain of the first transistor is electrically connected to the first pixel electrode,
wherein one of a source and a drain of the second transistor is electrically connected to the second pixel electrode, and
wherein the first transistor and the second transistor contain a metal oxide in a channel formation region.

5. A method for manufacturing a display device comprising:
a first step of forming a first pixel electrode, a second pixel electrode, and a connection electrode;
a second step of sequentially depositing a first light-emitting film, an intermediate film, and a second light-emitting film over the first pixel electrode and the second pixel electrode;
a third step of forming a first sacrificial film over the second light-emitting film and the connection electrode;
a fourth step of exposing the second pixel electrode by etching the first sacrificial film, the second light-emitting film, the intermediate film, and the first light-emitting film and forming a first light-emitting layer over the first pixel electrode, an intermediate layer over the first light-emitting layer, a second light-emitting layer over the intermediate layer, and a first sacrificial layer over the second light-emitting layer and the connection electrode;
a fifth step of depositing a light-receiving film over the first sacrificial layer and the second pixel electrode;
a sixth step of forming a second sacrificial film over the light-receiving film;
a seventh step of forming a light-receiving layer over the second pixel electrode and a second sacrificial layer over the light-receiving layer by etching the second sacrificial film and the light-receiving film;
an eighth step of removing the first sacrificial layer and the second sacrificial layer; and
a ninth step of forming a common electrode over the second light-emitting layer and the light-receiving layer so that the common electrode includes a region in contact with the connection electrode.

6. The method for manufacturing a display device according to claim 5, wherein the first light-emitting film, the second light-emitting film, and the light-receiving film are formed by an evaporation method using a shielding mask.

7. The method for manufacturing a display device according to claim 5,
wherein the first sacrificial film and the second sacrificial film contain the same metal film, alloy film, metal oxide film, semiconductor film, or inorganic insulating film,
wherein in the fourth step, the first light-emitting film and the second light-emitting film are etched by dry etching using an etching gas not containing oxygen as a main component, and
wherein in the eighth step, the first sacrificial layer and the second sacrificial layer are removed by wet etching using a tetramethyl ammonium hydroxide aqueous solution, diluted hydrofluoric acid, oxalic acid, phosphoric acid, acetic acid, nitric acid, or a mixed solution thereof.

8. The method for manufacturing a display device according to claim 7, wherein the first sacrificial film and the second sacrificial film contain aluminum oxide.

9. The method for manufacturing a display device according to claim 5, further comprising a tenth step of forming a protective layer over the common electrode after the ninth step.

10. A display device comprising:
a first light-emitting element;
a second light-emitting element; and
a light-receiving element,
wherein the first light-emitting element comprises:
a first pixel electrode;
a first light-emitting layer over the first pixel electrode;
an intermediate layer over the first light-emitting layer;
a second light-emitting layer over the intermediate layer;
a common layer over the second light-emitting layer; and
a common electrode over the common layer,
wherein the light-receiving element comprises:
a second pixel electrode;
a light-receiving layer over the second pixel electrode;
the common layer over the light-receiving layer; and
the common electrode over the common layer,
wherein in the first light-emitting element, the common layer is configured to serve as one of a hole-injection layer and an electron-injection layer, and
wherein the second light-emitting element is configured to emit infrared light or near-infrared light.
